(19) United States
(12) Patent Application Publication
(10) Pub. No.: US 2025/0210933 A1
(43) Pub. Date: Jun. 26, 2025

(54) LIGHT-EMITTING DEVICE, LIGHT-EMITTING MODULE, AND PLURALITY OF LIGHT-EMITTING DEVICES

(71) Applicant: NICHIA CORPORATION, Anan-shi (JP)

(72) Inventor: Naoki SAKA, Tokushima-shi (JP)

(21) Appl. No.: 18/985,093

(22) Filed: Dec. 18, 2024

(30) Foreign Application Priority Data
Dec. 22, 2023 (JP) 2023-217042

(51) Int. Cl. H01S 5/02315; H01S 5/02255; H01S 5/02345; H01S 5/40

(52) U.S. Cl. CPC H01S 5/02315; H01S 5/02255; H01S 5/02345; H01S 5/40

(57) ABSTRACT

A light-emitting device includes first and second semiconductor laser elements, first and second protective elements, and first and second submounts. The second semiconductor laser element has a length greater than the first semiconductor laser element. In a top view, the first protective element is not placed between first and second virtual straight lines respectively passing through and parallel to the light-emitting surface and the first lateral surface of the first semiconductor laser element, and a part or all of the second protective element is placed between third and fourth virtual straight lines respectively passing through and parallel to the light-emitting surface and the first lateral surface of the second semiconductor laser element. In the top view, a midpoint of the light-emitting surface of each of the first and second semiconductor laser elements does not coincide with a midpoint of the first and second submounts, respectively.

### CROSS-REFERENCE TO RELATED APPLICATION

This application claims priority to Japanese Patent Application No. 2023-217042, filed on Dec. 22, 2023, the disclosure of which is hereby incorporated herein by reference in its entirety.

### TECHNICAL FIELD

The present disclosure relates to a light-emitting device, a light-emitting module, and a plurality of light-emitting devices including a first light-emitting device and a second light-emitting device.

### BACKGROUND

Japanese Patent Publication No. 2023-164346 discloses that, when the light-emitting surface of a semiconductor laser element is the front side surface thereof, the semiconductor laser element and a protective element are arranged so that the protective element is located further rearward from the rear side surface of the semiconductor laser element on the mounting surface of a submount.

### SUMMARY

The present disclosure discloses a light-emitting device or a light-emitting module in which submounts having the same design can respectively be used in common for two semiconductor laser elements having mutually different lengths in a resonator direction (i.e., a direction perpendicular to the light-emitting surface of the semiconductor laser elements).

Alternatively, instead of the above-mentioned aspect, the present disclosure discloses a plurality of light-emitting devices that allow the respective use of submounts having the same design in common for a first light-emitting device and a second light-emitting device in which semiconductor laser elements having mutually different lengths in a resonator direction are mounted.

Alternatively, instead of the above-mentioned aspects, the present disclosure discloses a light-emitting device or a light-emitting module that can achieve a small light-emitting device.

Alternatively, instead of the above-mentioned aspects, the present disclosure discloses a light-emitting device or a light-emitting module that can emit light with which optical design is facilitated.

Alternatively, instead of the above-mentioned aspects, the present disclosure discloses a plurality of light-emitting devices including a first light-emitting device and a second light-emitting device in which a deviation in the light emitting position can be reduced when mounted in the same orientation and when mounted facing each other.

In the present specification, an embodiment directed to the plurality of aspects among the above-described aspects in combination is also disclosed.

A light-emitting device disclosed in an embodiment includes a plurality of semiconductor laser elements, a plurality of protective elements, and a plurality of submounts. The semiconductor laser elements include a first semiconductor laser element and a second semiconductor laser element each having a light-emitting surface and a first lateral surface opposite to the light-emitting surface. The second semiconductor laser element has a length greater than a length of the first semiconductor laser element in a resonator direction that is perpendicular to the light-emitting surface of a corresponding one of the first semiconductor laser element and the second semiconductor laser element. The protective elements include a first protective element and a second protective element. The submounts include a first submount and a second submount. The first semiconductor laser element and the first protective element are disposed on the first submount. The second semiconductor laser element and the second protective element are disposed on the second submount. Each of the first submount and the second submount includes a mounting surface on which a wiring layer is provided. The wiring layer includes a first region on which a corresponding one of the first semiconductor laser element and the second semiconductor laser element is disposed, and a second region on which a corresponding one of the first protective element and the second protective element is disposed. In a top view, the first protective element is not placed between a first virtual straight line and a second virtual straight line. The first virtual straight line passes through and is parallel to the light-emitting surface of the first semiconductor laser element. The second virtual straight line passes through and is parallel to the first lateral surface of the first semiconductor laser element. In the top view, a part or all of the second protective element is placed between a third virtual straight line and a fourth virtual straight line. The third virtual straight line passes through and is parallel to the light-emitting surface of the second semiconductor laser element. The fourth virtual straight line passes through and is parallel to the first lateral surface of the second semiconductor laser element. In the top view, a midpoint of a width of the light-emitting surface of the first semiconductor laser element does not coincide with a midpoint of a width of the first submount in a direction parallel to the light-emitting surface of the first semiconductor laser element. In the top view, a midpoint of a width of the light-emitting surface of the second semiconductor laser element does not coincide with a midpoint of a width of the second submount in a direction parallel to the light-emitting surface of the second semiconductor laser element.

A light-emitting module disclosed in an embodiment includes a first light-emitting device, a second light-emitting device, and a mounting substrate. The first light-emitting device includes a plurality of first semiconductor laser elements, a plurality of first protective elements, and a plurality of first submounts. The first semiconductor laser elements each has a light-emitting surface and a first lateral surface opposite to the light-emitting surface. The first submounts each includes a first mounting surface on which a first wiring layer is provided. The first wiring layer includes a first region and a second region. The first region is a region on which a corresponding one of the first semiconductor laser elements is disposed, and the second region is a region on which a corresponding one of the first protective elements is disposed. The second light-emitting device includes a plurality of second semiconductor laser elements, a plurality of second protective elements, and a plurality of second submounts. The second semiconductor laser elements each has a light-emitting surface and a second lateral surface opposite to the light-emitting surface. The second submounts each includes a second mounting surface on which a second wiring layer is provided. The second wiring layer includes a first region and a second region. The first region is a region on which a corresponding one of the second semiconductor laser elements is disposed, and the second region is a region on which a corresponding one of the second protective elements is disposed. The first light-emitting device and the second light-emitting device are mounted on the mounting substrate. A shape of the first wiring layer of each of the first submounts when viewed from a direction perpendicular to the first mounting surface is identical to a shape of the second wiring layer of each of the second submounts when viewed from a direction perpendicular to the second mounting surface. In a top view, each of the first protective elements is not placed between a first virtual straight line and a second virtual straight line. The first virtual straight line passes through and is parallel to the light-emitting surface of a corresponding one of the first semiconductor laser elements, and the second virtual straight line passes through and is parallel to the first lateral surface of the corresponding one of the first semiconductor laser elements. In the top view, a part or all of each of the second protective elements is placed between a third virtual straight line and a fourth virtual straight line. The first virtual straight line passes through and is parallel to the light-emitting surface of a corresponding one of the second semiconductor laser elements, and the fourth virtual straight line passes through and is parallel to the first lateral surface of the corresponding one of the second semiconductor laser elements. In the top view, a midpoint of a width of the light-emitting surface of each of the first semiconductor laser elements does not coincide with a midpoint of a width of a corresponding one of the first submounts in a direction parallel to the light-emitting surface of each of the first semiconductor laser elements. In the top view, a midpoint of a width of the light-emitting surface of each of the second semiconductor laser elements does not coincide with a midpoint of a width of a corresponding one of the second submounts in a direction parallel to the light-emitting surface of each of the second semiconductor laser elements.

A plurality of light-emitting devices disclosed in an embodiment include a first light-emitting device and a second light-emitting device. The first light-emitting device includes a plurality of first semiconductor laser elements each having a light-emitting surface and a first lateral surface opposite to the light-emitting surface, a plurality of first protective elements, and a plurality of first submounts each including a first mounting surface on which a first wiring layer is provided, the first wiring layer including a first region and a second region, the first region being a region on which a corresponding one of the first semiconductor laser elements is disposed, and the second region being a region on which a corresponding one of the first protective elements is disposed. The second light-emitting device includes a plurality of second semiconductor laser elements each having a light-emitting surface and a second lateral surface opposite to the light-emitting surface, a plurality of second protective elements, and a plurality of second submounts each including a second mounting surface on which a second wiring layer is provided, the second wiring layer including a first region and a second region, the first region being a region on which a corresponding one of the second semiconductor laser elements is disposed, and the second region being a region on which a corresponding one of the second protective elements is disposed. A shape of the first wiring layer of each of the first submounts when viewed from a direction perpendicular to the first mounting surface is identical to a shape of the second wiring layer of each of the second submounts when viewed from a direction perpendicular to the second mounting surface. In a top view, each of the first protective elements is not placed between a first virtual straight line and a second virtual straight line. The first virtual straight line passes through and is parallel to the light-emitting surface of a corresponding one of the first semiconductor laser elements, and the second virtual straight line passes through and is parallel to the first lateral surface of the corresponding one of the first semiconductor laser elements. In the top view, a part or all of each of the second protective elements is placed between a third virtual straight line and a fourth straight line. The third straight line passes through and is parallel to the light-emitting surface of a corresponding one of the second semiconductor laser elements, and the fourth virtual straight line passes through and is parallel to the first lateral surface of the corresponding one of the second semiconductor laser elements. In the top view, a midpoint of a width of the light-emitting surface of each of the first semiconductor laser elements does not coincide with a midpoint of a width of a corresponding one of the first submounts in a direction parallel to the light-emitting surface of each of the first semiconductor laser elements. In the top view, a midpoint of a width of the light-emitting surface of each of the second semiconductor laser elements does not coincide with a midpoint of a width of a corresponding one of the second submounts in a direction parallel to the light-emitting surface of each of the second semiconductor laser elements.

According to at least one of or a plurality of embodiments, the submounts of the same design can be respectively used in common for two semiconductor laser elements having mutually different lengths corresponding to resonators' lengthwise direction.

### BRIEF DESCRIPTION OF DRAWINGS

FIG. 1 is a schematic perspective view of a light-emitting device according to some embodiments.

FIG. 2 is a schematic side view of the light-emitting device according to some embodiments.

FIG. 3 is a schematic cross-sectional view of a light-emitting device according to a first embodiment and a third embodiment taken along a cross-sectional line III-III in FIG. 1.

FIG. 4 is a schematic top view for explaining an internal structure of the light-emitting device according to the first embodiment.

FIG. 5 is a schematic top view illustrating a state in which wirings are removed from FIG. 4.

FIG. 6 is a schematic top view of the submount according to some embodiments.

FIG. 7A is a schematic top view illustrating a state in which a first semiconductor laser element and a protective element are disposed on the submount.

FIG. 7B is a schematic top view illustrating a state in which a second semiconductor laser element and a protective element are disposed on the submount.

FIG. 8 is a schematic side view illustrating a state in which the semiconductor laser element and the protective element are disposed on the submount.

FIG. 9 is a schematic perspective view of a package according to some embodiments.

FIG. 10 is a schematic cross-sectional view of the package taken along a cross-sectional line X-X illustrated in FIG. 9.

FIG. 11 is a schematic top view of a base according to some embodiments.

FIG. 12 is a schematic bottom view of the base according to some embodiments.

FIG. 13 is a schematic cross-sectional view of the base taken along a cross-sectional line XIII-XIII in FIG. 11.

FIG. 14A is a schematic top view for explaining an example of an internal structure of a light-emitting device according to a second embodiment.

FIG. 14B is a schematic top view illustrating a state in which a first semiconductor laser element and a protective element are disposed on a submount in an example of the light-emitting device according to the second embodiment.

FIG. 14C is a schematic side view illustrating a state in which the semiconductor laser element and the protective element are disposed on the submount of the light-emitting device according to the second embodiment.

FIG. 15A is a schematic top view for explaining another example of the internal structure of the light-emitting device according to the second embodiment.

FIG. 15B is a schematic top view illustrating a state in which the second semiconductor laser element and the protective element are disposed on the submount in another example of the light-emitting device according to the second embodiment.

FIG. 16 is a schematic perspective view of a light-emitting module according to a third embodiment.

FIG. 17A is a schematic top view for explaining an internal structure of a first light-emitting device according to the third embodiment.

FIG. 17B is a schematic top view illustrating a state in which wirings are removed from FIG. 17A.

FIG. 17C is a schematic top view for explaining an internal structure of a second light-emitting device according to the third embodiment.

FIG. 17D is a schematic top view illustrating a state in which wirings are removed from FIG. 17C.

FIG. 18 is a schematic top view of a wiring substrate according to the third embodiment.

FIG. 19 is a schematic top view for explaining the internal structure of the first light-emitting device and the second light-emitting device in the light-emitting module according to the third embodiment.

### DESCRIPTION OF EMBODIMENTS

In the present specification or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present specification and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present specification or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the opposite directions are the negative directions. For example, the direction marked with X at the tip of the arrow is the X direction and the positive direction. In the present specification, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction.

In addition, in the present specification, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In addition, in the present specification, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present specification. The term “member” refers to an object physically treated alone. The object physically treated alone can be an object treated as one part in a manufacturing process. Meanwhile, the term “portion” refers to an object that need not be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present disclosure.

In the present specification or the claims, when a plurality of components are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, when components distinguished by being termed “first”, “second”, and “third” are present in the present specification, and when components given the terms “first” and “third” in the present specification are described in the claims, these components may be distinguished by being denoted as “first” and “second” in the claims for ease of understanding. In this case, the components denoted as “first” and “second” in the claims refer to the components termed “first” and “third” in the present specification, respectively. This rule applies to not only components but also other objects in a reasonable and flexible manner.

An embodiment for implementing the present invention will be described below. A specific embodiment for implementing the present invention will be described below with reference to the drawings. An embodiment for implementing the present invention is not limited to the specific embodiment. That is, the embodiment illustrated by the drawings is not the only form in which the present invention is implemented. Sizes and positional relationships of members illustrated in each of the drawings may sometimes be exaggerated in order to facilitate understanding.

### First Embodiment

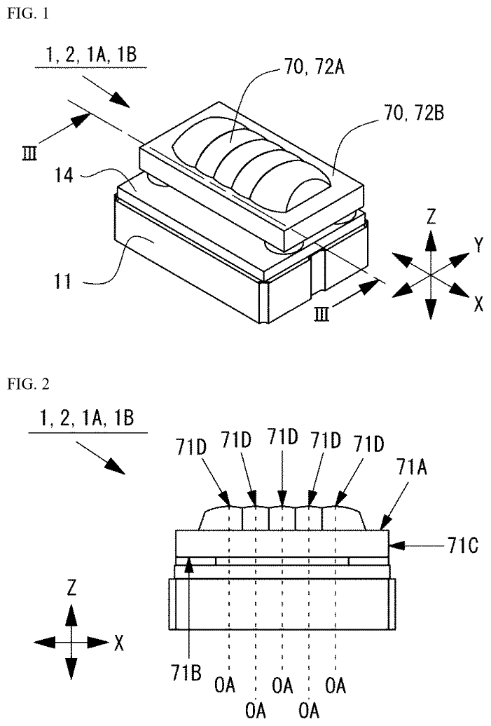

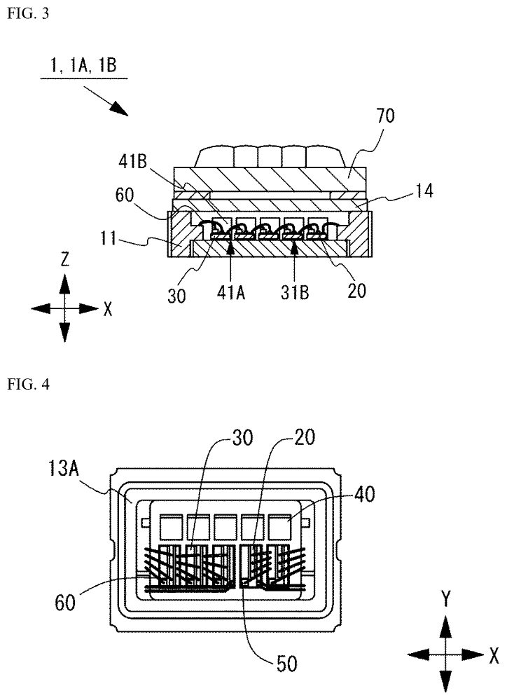

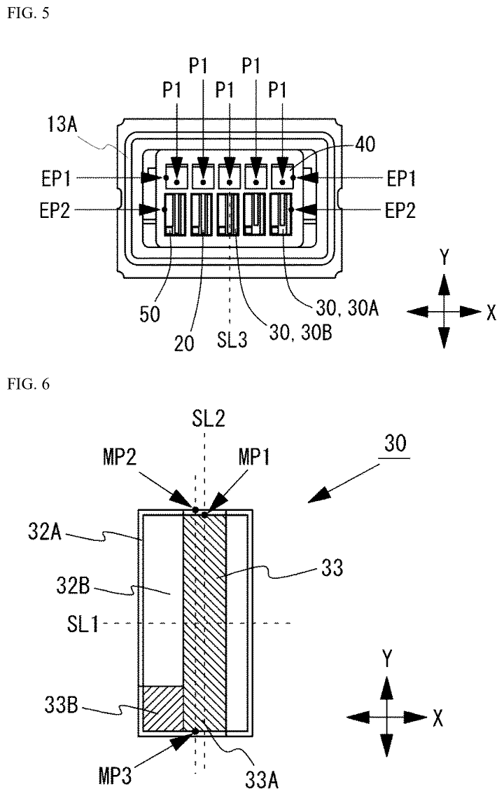

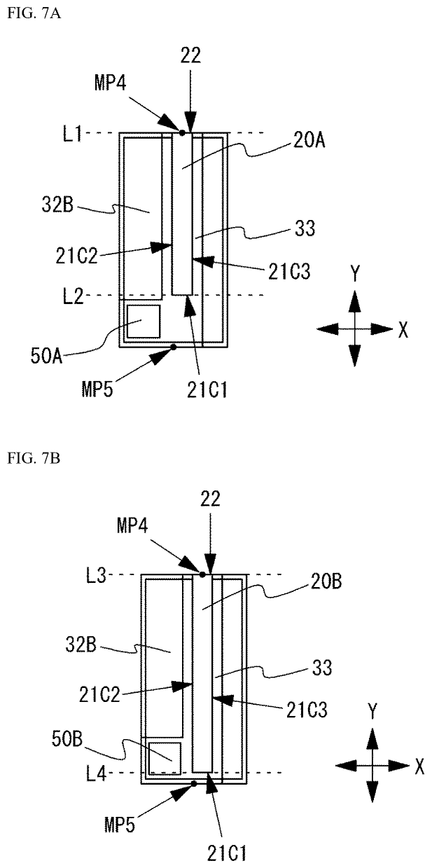

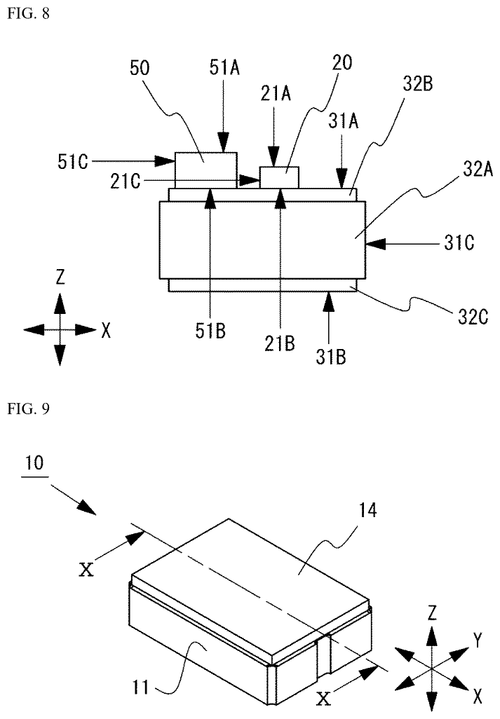

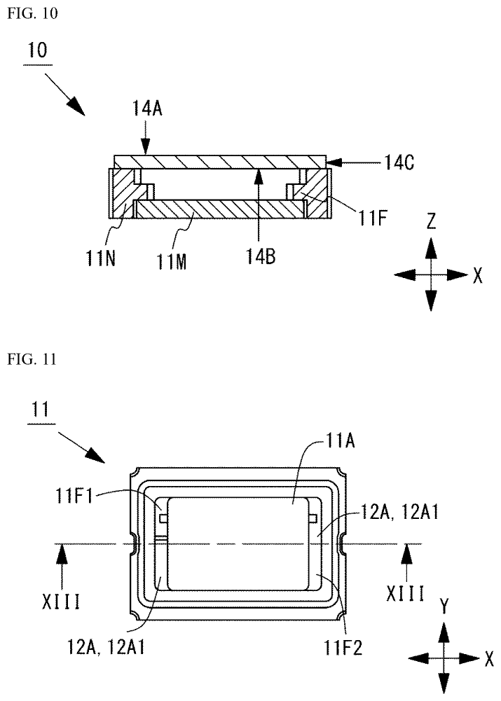

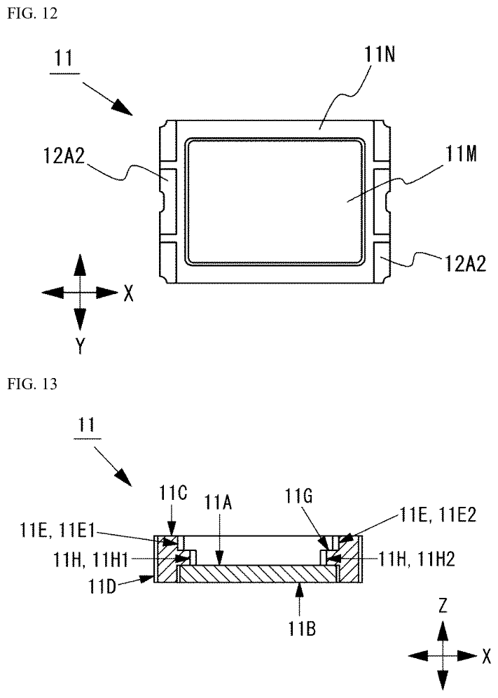

A light-emitting device 1 according to a first embodiment will now be described. FIGS. 1 to 13 are schematic drawings for explaining an exemplary form of the light-emitting device 1. FIG. 1 is a schematic perspective view of the light-emitting device 1. FIG. 2 is a schematic side view of the light-emitting device 1. FIG. 3 is a schematic cross-sectional view of the light-emitting device 1 taken along a cross-sectional line III-III in FIG. 1. FIG. 4 is a schematic top view for explaining an internal structure of the light-emitting device 1. FIG. 5 is a schematic top view illustrating a state in which wirings 60 are removed from FIG. 4. FIG. 6 is a schematic top view of the submount 30. FIG. 7A is a schematic top view illustrating a state in which a first semiconductor laser element 20A and a first protective element 50A are disposed on a first submount 30A. FIG. 7B is a schematic top view illustrating a state in which a second semiconductor laser element 20B and a second protective element 50B are disposed on a second submount 30B. FIG. 8 is a schematic side view illustrating a state in which a semiconductor laser element 20 and a protective element 50 are disposed on a submount 30. FIG. 9 is a schematic perspective view of a package 10. FIG. 10 is a schematic cross-sectional view of the package 10 taken along a cross-sectional line X-X in FIG. 9. FIG. 11 is a schematic top view of a base 11. FIG. 12 is a schematic bottom view of the base 11. FIG. 13 is a schematic cross-sectional view of the base 11 taken along a cross-sectional line XIII-XIII in FIG. 11.

The light-emitting device 1 includes a plurality of components. The plurality of components include the package 10, one or more semiconductor laser elements 20, one or more submounts 30, one or more reflective members 40, one or more protective elements 50, a plurality of wirings 60, and an optical member 70.

The light-emitting device 1 may include a component other than the components described above. For example, the light-emitting device 1 may further include a semiconductor laser element different from the one or more semiconductor laser elements 20. The light-emitting device 1 need not include some of the components described above.

Firstly, each of the components will be described.

### Package 10

The package 10 includes the base 11 and a lid body 14. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the illustrated package 10, the long-side direction of the rectangular shape is the same direction as the X direction, and the short-side direction of the rectangular shape is the same direction as the Y direction. The outer edge shape of the package 10 in a top view need not be rectangular.

The internal space in which other components are disposed is formed in the package 10. A first upper surface 11A of the package 10 is a part of a region defining the internal space. In addition, inner lateral surfaces 11E and the lower surface 14B of the package 10 are a part of the region defining the internal space.

The base 11 has the first upper surface 11A and a lower surface 11B. The base 11 has a second upper surface 11C. The base 11 has one or more outer lateral surfaces 11D. The base 11 has one or more inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The outer edge shape of the base 11 in a top view is rectangular. The outer edge shape of the base 11 in a top view is the outer edge shape of the package 10. The outer edge shape of the first upper surface 11A in a top view is rectangular. This rectangular shape can be a rectangular shape with long sides and short sides. The long-side direction of the first upper surface 11A is parallel to the long-side direction of the outer edge shape of the base 11. The outer edge shape of the first upper surface 11A in a top view need not be rectangular.

In a top view, the first upper surface 11A is surrounded by the second upper surface 11C. The second upper surface 11C is an annular surface surrounding the first upper surface 11A in a top view. The second upper surface 11C is a rectangular annular surface. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

The base 11 has a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion. The second upper surface 11C is located above the first upper surface 11A.

The base 11 includes one or more step portions 11F. Each of the step portions 11F includes an upper surface 11G and a lateral surface 11H that meets the upper surface 11G and extends downward from the upper surface 11G. Here, one step portion 11F has only one upper surface 11G and only one lateral surface 11H. The upper surface 11G meets the inner lateral surface 11E. The lateral surface 11H meets the first upper surface 11A.

One or each of the step portions 11F is formed on an inner side of the inner frame of the second upper surface 11C in a top view. One or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are perpendicular to the first upper surface 11A. The term “perpendicular” as used here allows for a difference within ±3 degrees.

The one or more step portions 11F can include a first step portion 11F1 and a second step portion 11F2. The first step portion 11F1 and the second step portion 11F2 are provided at positions where the respective lateral surfaces 11H are opposed to each other. The first step portion 11F1 and the second step portion 11F2 are provided on sides of the short sides of the inner frame of the second upper surface 11C.

One or each of the inner lateral surfaces 11E and one or each of the lateral surfaces 11H are located between the first upper surface 11A and the second upper surface 11C. The one or more inner lateral surfaces 11E include a first inner lateral surface 11E1 and a second inner lateral surface 11E2 which face each other. The base 11 has a plurality of lateral surfaces 11H including a first lateral surface 11H1 and a second lateral surface 11H2 which face each other.

The first inner lateral surface 11E1 meets the upper surface 11G of the first step portion 11F1. The second inner lateral surface 11E2 meets the upper surface 11G of the second step portion 11F2. The first lateral surface 11H1 is the lateral surface 11H of the first step portion 11F1, and the second lateral surface 11H2 is the lateral surface 11H of the second step portion 11F2.

The base 11 includes a base portion 11M and a frame portion 11N. The base portion 11M and the frame portion 11N may be members made of mutually different materials. The base 11 can include a base member corresponding to the base portion 11M and a frame member corresponding to the frame portion 11N.

The base portion 11M has the first upper surface 11A. The frame portion 11N has the second upper surface 11C. The frame portion 11N has the one or more outer lateral surfaces 11D and the one or more inner lateral surfaces 11E. The frame portion 11N includes the one or more step portions 11F.

The lower surface of the base portion 11M constitutes a part or the entire region of the lower surface 11B of the base 11. When the lower surface of the base portion 11M constitutes a part of the region of the lower surface 11B of the base 11, the lower surface of the frame portion 11N constitutes the remaining region of the lower surface 11B of the base 11.

The base 11 includes a plurality of wiring portions 12A. The wiring portions 12A include one or more first wiring portions 12A1 disposed in the internal space of the package 10 and one or more second wiring portions 12A2 provided on the outer surface of the package 10.

One or each of the first wiring portions 12A1 is provided on the upper surface 11G of the step portion 11F. The base 11 includes the one or more first wiring portions 12A1 provided on the upper surface 11G of the first step portion 11F1. The base 11 includes the one or more first wiring portions 12A1 provided on the upper surface 11G of the second step portion 11F2.

One or each of the second wiring portions 12A2 is provided on the lower surface 11B of the package 10. One or each of the second wiring portions 12A2 is provided on the lower surface of the frame portion 11N. The second wiring portion 12A2 may be provided on an outer surface different from the lower surface 11B of the package 10.

When the base 11 is divided into two regions by a virtual line passing through the lateral surface 11H of the first step portion 11F1 and parallel to the lateral surface 11H in a top view, the base 11 has the one or more second wiring portions 12A2 provided on the lower surface 11B of the base 11 in a region including the upper surface 11G of the first step portion 11F1.

When the base 11 is divided into two regions by a virtual line passing through the lateral surface 11H of the second step portion 11F2 and parallel to the lateral surface 11H in a top view, the base 11 has the one or more second wiring portions 12A2 provided on the lower surface 11B of the base 11 in a region including the upper surface 11G of the second step portion 11F2.

In the base 11, one or each of the first wiring portions 12A1 is electrically connected to the second wiring portion 12A2. The one or more first wiring portions 12A1 are electrically connected to the mutually different second wiring portions 12A2.

The base 11 includes a bonding pattern 13A. The bonding pattern 13A is provided on the second upper surface 11C. The bonding pattern 13A is provided annularly. The bonding pattern 13A is provided in a rectangular annular shape. In a top view, the first upper surface 11A is surrounded by the bonding pattern 13A.

The base 11 can be formed using a ceramic as a main material, for example. Examples of the ceramic as the main material of the base 11 include aluminum nitride, silicon nitride, aluminum oxide, and silicon carbide.

Here, a main material refers to a material that accounts for the greatest proportion of a target formed product in terms of mass or volume. When a target formed product is formed of a single material, the material is the main material. In other words, when a certain material is the main material, the proportion of the material may be 100%.

The base 11 may be formed using a base member and a frame member formed of main materials different from each other. The base member can be formed using a main material having excellent heat dissipation, for example, a metal or a composite containing a metal, graphite, or diamond. Examples of the metal as the main material of the base member include, for example, copper, aluminum, and iron. Examples of the composite containing the metal as the main material of the base member include, for example, copper-molybdenum and copper-tungsten. The frame member can be formed using, as a main material, for example, any of the ceramics exemplified above as the main material of the base 11.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can be constituted by one or more metal layers, for example.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can be constituted by one or more metal layers, for example.

The lid body 14 has an upper surface 14A and a lower surface 14B. The lid body 14 also has one or more lateral surfaces 14C. The lid body 14 is formed of a flat plate with a rectangular parallelepiped shape. The lid body 14 does not necessarily have a rectangular parallelepiped shape.

The lid body 14 is bonded to the base 11. The lower surface 14B of the lid body 14 is bonded to the second upper surface 11C of the base 11. The lid body 14 is bonded to the bonding pattern 13A of the base 11. The lid body 14 is bonded to the base 11 via an adhesive.

The lid body 14 has transmissivity to transmit light. The term “transmissivity” as used here refers to the transmittance for light incident on the lid body 14 being equal to or more than 80%. The lid body 14 may partially include a non-light transmitting region (a region with no transmissivity).

The lid body 14 can be formed using glass as a main material, for example. The lid body 14 can also be formed using sapphire as a main material, for example.

### Semiconductor Laser Element 20

The semiconductor laser element 20 has an upper surface 21A, a lower surface 21B, and a plurality of lateral surfaces 21C. A shape of the upper surface 21A is a rectangle having long sides and short sides. An outer shape of the semiconductor laser element 20 in a top view is a rectangle having long sides and short sides. The shape of the upper surface 21A and the outer shape of the semiconductor laser element 20 in the top view are not limited thereto.

The semiconductor laser element 20 has a light-emitting surface 22 from which light is emitted. For example, the lateral surface 21C may serve as the light-emitting surface 22. The lateral surface 21C serving as the light-emitting surface 22 meets a short side of the upper surface 21A. For example, the upper surface 21A can serve as the light-emitting surface 22.

The plurality of lateral surfaces 21C include a first lateral surface 21C1 which is a surface located on the side opposite to the light-emitting surface 22. The first lateral surface 21C1 meets a short side of the upper surface 21A. In the semiconductor laser element 20, a resonator is elongated in a direction perpendicular to the light-emitting surface 22. A direction perpendicular to the light-emitting surface 22 is referred to as a resonator direction.

The length of the semiconductor laser element 20 in the resonator direction is greater than the length of the semiconductor laser element 20 in the direction parallel to the light-emitting surface 22. In the illustrated semiconductor laser element 20, the resonator direction of the semiconductor laser element 20 is the same direction as the Y direction. The resonator direction is parallel to a direction in which the long side of the outer shape of the semiconductor laser element 20 extends in a top view.

As the semiconductor laser element 20, a single-emitter semiconductor laser element including one emitter can be employed. As the semiconductor laser element 20, a multi-emitter semiconductor laser element including a plurality of emitters can be employed.

As the semiconductor laser element 20, for example, a semiconductor laser element that emits blue light can be employed. Also, for example, as the semiconductor laser element 20, a semiconductor laser element that emits green light can be employed. Also, for example, as the semiconductor laser element 20, a semiconductor laser element that emits red light can be employed. A semiconductor laser element that emits light of another color or light having another wavelength may be employed as the semiconductor laser element 20.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the semiconductor laser element 20 that emits blue light or the semiconductor laser element 20 that emits green light include a semiconductor laser element including a nitride semiconductor. A GaN-based semiconductor, such as GaN, InGaN, or AlGaN, can be employed as the nitride semiconductor. Examples of the semiconductor laser element 20 that emits red light include a semiconductor laser element including an InAlGaP-based semiconductor, a GalnP-based semiconductor, or a GaAs-based semiconductor, such as GaAs or AlGaAs.

The semiconductor laser element 20 emits a directional laser beam. Divergent light that spreads is emitted from the light-emitting surface 22 (emission end surface) of the semiconductor laser element 20. The light emitted from the semiconductor laser element 20 forms a far-field pattern (hereinafter referred to as an “FFP”) with an elliptical shape in a plane parallel to the light-emitting surface 22. The FFP indicates a shape or a light intensity distribution of the emitted light at a position spaced apart from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to the peak intensity is referred to as main portion light.

The shape of the FFP of the light emitted from the semiconductor laser element 20 has an elliptical shape in which a length in a layering direction is longer than that in a direction perpendicular to the layering direction in the plane parallel to the light-emitting surface 22. The layering direction is a direction in which a plurality of semiconductor layers including an active layer are layered in the semiconductor laser element 20. The direction perpendicular to the layering direction can also be referred to as a plane direction of the semiconductor layer. A long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity spreads is referred to as a divergence angle of light of the semiconductor laser element 20. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the present specification, the term “divergence angle of light” by itself refers to a divergence angle of light at the light intensity of 1/e² of the peak light intensity.

The divergence angle in the fast axis direction of the light emitted from the semiconductor laser element 20 may be 10 degrees or more and less than 40 degrees. Also, the divergence angle of the light in the slow axis direction can be in a range exceeding 0 degree and equal to or less than 15 degrees. Also, the divergence angle of the light in the fast axis direction is greater than the divergence angle of the light in the slow axis direction.

For example, the divergence angle in the fast axis direction of blue light emitted from the semiconductor laser element 20 can be 15 degrees or more and less than 30 degrees, and the divergence angle in the slow axis direction thereof may be 2 degrees or more and less than 8 degrees. Also, for example, the divergence angle in the fast axis direction of green light emitted from the semiconductor laser element 20 can be 15 degrees or more and less than 30 degrees, and the divergence angle in the slow axis direction thereof may be in 2 degrees or more and less than 15 degrees. Also, for example, the divergence angle in the fast axis direction of red light emitted from the semiconductor laser element 20 can be 20 degrees or more and less than 40 degrees, and the divergence angle in the slow axis direction thereof may be 2 degrees or more and less than 10 degrees.

### Submount 30

The submount 30 has an upper surface 31A, a lower surface 31B, and one or more lateral surfaces 31C. It can be said that the upper surface 31A is a mounting surface on which other components are mounted. The shape of the upper surface 31A is rectangular. The rectangular shape of the upper surface 31A can have short sides and long sides. The shape of the upper surface 31A need not be rectangular.

The outer shape of the submount 30 in a top view is rectangular. The rectangular shape of the submount 30 can have short sides and long sides. The outer shape of the submount 30 in a top view need not be rectangular. The submount 30 can have an outer shape having a length in one direction (hereinafter, the direction is referred to as a lateral direction of the submount 30) smaller than a length in a direction (hereinafter, the direction is referred to as a longitudinal direction of the submount 30) perpendicular to the one direction in a top view. In the submount 30 illustrated by the drawings, the lateral direction is the same direction as the X direction, and the longitudinal direction is the same direction as the Y direction.

The submount 30 can include a substrate 32A and an upper metal member 32B. The submount 30 can further include a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

The wiring layer 33 is provided on the upper surface 31A of the submount 30. Other components are disposed on the wiring layer 33. The wiring layer 33 has a first region 33A and a second region 33B. Different components are disposed in the first region 33A and the second region 33B.

The wiring layer 33 has a rectangular region in which the length in the longitudinal direction is greater than the width in the lateral direction in a top view, and a projecting region extending in the lateral direction from the rectangular region. The projecting shape extends from a corner of the rectangle in the lateral direction. In other words, one side extending in the lateral direction of the wiring layer 33 includes a side extending in the lateral direction in the rectangular region and a side extending in the lateral direction in the projecting region.

The first region 33A includes this rectangular region in a top view. The second region 33B includes this projecting region in a top view. In the illustrated submount 30, the rectangular region is the first region 33A, and the projecting region is the second region 33B. The projecting region has a rectangular shape in which the ratio of the length in the longitudinal direction to the width in the lateral direction is smaller than that of the rectangular shape of the first region 33A.

Here, the midpoint of the width of the first region 33A in the lateral direction of the submount 30 is referred to as a midpoint MP1, the midpoint of the width of the submount 30 in the lateral direction of the submount 30 is referred to as a midpoint MP2, and the midpoint of the width of the upper surface 31A in the lateral direction of the submount 30 is referred to as a midpoint MP3.

In a top view, the midpoint MP1 of the first region 33A does not coincide with the midpoint MP2 of the submount 30 in the lateral direction. In a top view, the midpoint MP1 of the first region 33A does not coincide with the midpoint MP3 of the upper surface 31A in the lateral direction. In a top view, the midpoint MP2 of the submount 30 and the midpoint MP3 of the upper surface 31A coincide with each other in the lateral direction. The term “coincide” as used here allows for a difference within ±60 μm.

By making the midpoint MP1 not coinciding with the midpoint MP2 or the midpoint MP3, the width in the lateral direction in which the second region 33B can be provided is greater than when the midpoint MP1 coincides with the midpoint MP2 or the midpoint MP3. This facilitates mounting of the component disposed in the first region 33A and the component disposed in the second region 33B without bringing them into contact with each other, thereby improving productivity.

In a top view, a distance from the midpoint MP2 to the midpoint MP1 in the lateral direction is in a range from 100 μm to 200 μm. This distance is preferably in a range from 45 μm to 85 μm. Setting the distance to 45 μm or more facilitates mounting of the component disposed in the first region 33A and the component disposed in the second region 33B without bringing them into contact with each other. Setting the distance to 85 μm or less can suppress, to a certain extent, the deterioration of the heat dissipation performance of the component disposed in the first region 33A. The allowable upper limit of this distance can be determined depending on the degree of heat dissipation needed for the component disposed in the first region 33A.

A difference between the length of the first region 33A and the length of the upper surface 31A in the longitudinal direction of the submount 30 is in a range from 0 μm to 130 μm. The wiring layer 33 is formed such that the first region 33A has a length close to the length of the mounting surface of the submount 30 in the longitudinal direction. The second region 33B extends from the boundary with the first region 33A to the end of the upper surface 31A in the lateral direction of the submount 30.

In a top view, the length of the second region 33B is equal to or less than one fourth of the length of the first region 33A in the longitudinal direction. In a top view, a virtual straight line SL1, which passes through the midpoint of the length in the longitudinal direction of the submount 30 and is parallel to the lateral direction of the submount 30, passes through the first region 33A and does not pass through the second region 33B.

The substrate 32A has an insulating property. The substrate 32A is formed of, for example, silicon nitride, aluminum nitride, or silicon carbide. It is preferable to select a ceramic with relatively good heat dissipation (having high thermal conductivity) as the main material of the substrate 32A.

A metal such as copper or aluminum is used as the main material of the upper metal member 32B. The upper metal member 32B includes one or more metal layers. The upper metal member 32B can include a plurality of metal layers formed using different metals as main materials.

A metal such as copper or aluminum is used as the main material of the lower metal member 32C. The lower metal member 32C includes one or more metal layers. The lower metal member 32C can include a plurality of metal layers formed using different metals as main materials.

The wiring layer 33 can be formed using a metal. For example, the wiring layer 33 can be formed using AuSn solder (a metal layer of AuSn).

For example, the width of the submount 30 in the short-side direction or the lateral direction is in a range from 600 μm to 900 μm. The length of the submount 30 in the long-side direction or the longitudinal direction is in a range from 1300 μm to 1800 μm. A difference between the length in the longitudinal direction of the submount 30 and the width in the lateral direction of the submount 30 is in a range from 500 μm to 900 μm.

For example, the thickness of the submount 30 (the width in a direction perpendicular to the upper surface 31A) is in a range from 200 μm to 400 μm. Also, for example, the thickness of the substrate 32A is in a range from 140 μm to 260 μm. Also, for example, the thickness of the upper metal member 32B is in a range from 30 μm to 70 μm. Also, for example, the thickness of the lower metal member 32C is in a range from 30 μm to 70 μm. Also, for example, the thickness of the wiring layer 33 is in a range from 1 μm to 5 μm.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass or metal can be used. A heat-resistant material is preferably used as the main material of the reflective member 40. As the main material, for example, a glass such as quartz glass or borosilicate glass (BK7), or a metal such as A1 can be used. The reflective member 40 can also be formed using Si as the main material.

When the main material is a reflective material such as A1, the light-reflective surface 41B can be formed of the main material. Instead of forming the light-reflective surface 41B with the main material, a general form of the reflective member 40 may be formed with the main material, and the light-reflective surface 41B may be formed on a surface of the general form. In this case, the light-reflective surface 41B can be formed using, for example, a layer of a metal such as Ag or Al, or a dielectric multilayer film of Ta₂O₅/SiO₂, TiO₂/SiO₂, or Nb₂O₅/SiO₂.

In the light-reflective surface 41B, the reflectance with respect to the peak wavelength of the light with which the light-reflective surface 41B is irradiated is equal to or more than 90%. The reflectance may be equal to or more than 95%. The reflectance may be equal to or more than 99%. The light reflectance is equal to or less than 100%, or is less than 100%.

### Protective Element 50

The protective element 50 has an upper surface 51A, a lower surface 51B, and one or more lateral surfaces 51C. The shape of the protective element 50 is a rectangular parallelepiped. The shape of the protective element 50 need not be a rectangular parallelepiped.

The protective element 50 prevents breakage of a specific element (the semiconductor laser element, for example) due to an excessive current flowing through the element. The protective element 50 is, for example, a Zener diode. A Zener diode formed of Si can be used.

### Wiring 60

The wiring 60 is a linear conductive material having bonding portions at both ends. The bonding portions at both ends serve as portions for bonding with other components. The wiring 60 is used for electrical connection between two components. The wiring 60 is, for example, a metal wire. The metal used can be, for example, gold, aluminum, silver, or copper.

### Optical Member 70

The optical member 70 has an upper surface 71A, a lower surface 71B, and one or more lateral surfaces 71C. The optical member 70 imparts an optical action to light that is incident on the optical member 70. Examples of the optical action imparted to the light by the optical member 70 include condensing, collimation, diffusion, polarization, diffraction, multiplexing, light guiding, reflection, and wavelength conversion.

The optical member 70 has an optical action surface that imparts the optical action. The upper surface 71A, the lower surface 71B, or the lateral surface 71C can serve as the optical action surface. Alternatively, the optical action surface may be provided at a position different from the upper surface 71A, the lower surface 71B, or the lateral surface 71C. For example, the optical action surface may be formed not on a surface of the optical member 70 but on an inner side of the optical member 70.

The optical member 70 can have one or more lens surfaces 71D. The lens surface 71D is the optical action surface of the optical member 70. The optical member 70 having the lens surface 71D may be referred to as a lens member. Light passing through the lens surface 71D and emitted from the optical member 70 is imparted an optical action of condensing, diffusion, or collimation by the optical member 70. For example, the optical member 70 is a collimating lens that collimates light that is incident on the optical member 70 and emits the collimated light.

One or each of the lens surfaces 71D is provided on the upper surface 71A side. Note that the lens surface 71D may be provided on the lower surface 71B side. The upper surface 71A and the lower surface 71B are flat surfaces. The one or each of the lens surfaces 71D meets the upper surface 71A. In a top view, the one or each of the lens surfaces 71D is surrounded by the upper surface 71A.

The outer shape of the optical member 70 in a top view is rectangular. The outer shape of the optical member 70 in a top view need not be rectangular. The lower surface 71B is a flat surface. The lens surface 71D is not formed on the lower surface 71B side of the optical member 70. The shape of the lower surface 71B is rectangular. The shape of the lower surface 71B need not be rectangular.

In the optical member 70, a portion overlapping with the lens surface 71D in a top view is a lens portion 72A. In the optical member 70, a portion overlapping with the upper surface 71A in a top view is a non-lens portion 72B. The lower surface 71B has a region constituting the lower surface of one or each of the lens portions 72A and a region constituting the lower surface of the non-lens portion 72B.

The optical member 70 can have a plurality of the lens surfaces 71D formed continuously in one direction. A direction in which the plurality of lens surfaces 71D are aligned in a top view is referred to as a coupling direction of the lenses. In the illustrated optical member 70, the coupling direction is the same direction as the X direction.

The plurality of lens surfaces 71D are formed such that the vertices of the respective lens surfaces 71D are provided on one straight line. The virtual straight line connecting the respective vertices is parallel to the lower surface 71B of the optical member 70. The term “parallel” as used here allows for a difference within ±5 degrees.

The curvatures of two or more lens surfaces 71D, that is, some or all of the plurality of lens surfaces 71D can be the same. The plurality of lens surfaces 71D can all have the same curvatures.

The optical member 70 has transmissivity. In the optical member 70, the transmittance with respect to the peak wavelength of light incident on the optical member 70 is equal to or more than 80%. The optical member 70 may include a region having transmissivity and a region having no transmissivity (hereinafter, referred to as a non-light transmitting region). In the non-light transmitting region, the transmittance with respect to the peak wavelength of light incident on the optical member 70 is equal to or less than 50%. The optical member 70 can be formed using, for example, glass such as BK7.

Next, the light-emitting device 1 will be described.

### Light-Emitting Device 1

The light-emitting device 1 includes a plurality of semiconductor laser elements 20 and a plurality of submounts 30. The plurality of semiconductor laser elements 20 include a first semiconductor laser element 20A and a second semiconductor laser element 20B having a longer length than the first semiconductor laser element 20A in the resonator direction. The light-emitting device 1 can include the plurality of semiconductor laser elements 20 including one or more first semiconductor laser elements 20A and one or more second semiconductor laser elements 20B.

The length of the second semiconductor laser element 20B in the resonator direction is greater than the length of the first semiconductor laser element 20A in the resonator direction by a range from 200 μm to 700 μm. The length of one or each of the second semiconductor laser elements 20B in the resonator direction is greater than the length of any of the first semiconductor laser elements 20A in the resonator direction by a range from 200 μm to 700 μm. By adjusting the length in the resonator direction, the output of light emitted from the semiconductor laser element 20 can be adjusted.

The light emission peak wavelength of light emitted from the first semiconductor laser element 20A is different from the light emission peak wavelength of light emitted from the second semiconductor laser element 20B by 30 nm or more. The emission peak wavelength of light emitted from the one or each of the first semiconductor laser elements 20A is different from the emission peak wavelength of light emitted from any of the second semiconductor laser element 20B by 30 nm or more. The difference between the emission peak wavelength of light emitted from the first semiconductor laser element 20A and the emission peak wavelength of light emitted from the second semiconductor laser element 20B may be less than 30 nm. Alternatively, this difference may be 10 nm or less.

The one or each of the first semiconductor laser elements 20A emits light whose emission peak wavelength is a first wavelength ±15 nm. The one or each of the second semiconductor laser elements 20B emits light whose emission peak wavelength is a second wavelength ±15 nm.

The one or each of the first semiconductor laser elements 20A emits light having a first color. The one or each of the second semiconductor laser element 20B emits light having a second color. The first color and the second color can be different. The color of the light emitted from the first semiconductor laser element 20A and the color of the light emitted from the second semiconductor laser element 20B may be the same.

Each of the semiconductor laser elements 20 is mounted on the submount 30. Each of the semiconductor laser elements 20 is disposed on the wiring layer 33 of the submount 30. Each of the semiconductor laser elements 20 is disposed in the first region 33A of the wiring layer 33.

The semiconductor laser element 20 is disposed on each of the plurality of submounts 30. One semiconductor laser element 20 is disposed on one submount 30. Here, to distinguish the plurality of submounts 30, the submount 30 on which the first semiconductor laser element 20A is disposed is referred to as a first submount 30A, and the submount 30 on which the second semiconductor laser element 20B is disposed is referred to as a second submount 30B.

The first submount 30A and the second submount 30B are the submounts 30 having the same shape. In a top view, the wiring layer 33 of the first submount 30A and the wiring layer 33 of the second submount 30B have the same shape.

For each of the semiconductor laser elements 20, a difference between the length of the first semiconductor laser element 20A in the direction parallel to the light-emitting surface 22 and a length of the second semiconductor laser element 20B in the direction parallel to the light-emitting surface 22 is in a range from 0 μm to 100 μm. Setting the difference to 100 μm or less can reduce the difference in the margin space on the mounting surface when mounting the first semiconductor laser element 20A and the second semiconductor laser element 20B on the submount 30 of the same design.

However, the length in the direction parallel to the light-emitting surface 22 of the one or each of the first semiconductor laser elements 20A may be greater than the length in the direction parallel to the light-emitting surface 22 of any or a specific second semiconductor laser element 20B by 100 μm or more.

For example, the light-emitting device 1 may be provided with one or more first semiconductor laser elements 20A whose length in the resonator direction is smaller than that of the second semiconductor laser element 20B by 200 μm or more, and whose length in the direction parallel to the light-emitting surface 22 is greater than that of the second semiconductor laser element 20B by a range from 0 μm to 100 μm.

Here, the midpoint of the width of the light-emitting surface 22 in the direction parallel to the light-emitting surface 22 in a top view is referred to as a midpoint MP4, and the midpoint of the width of the submount 30 in the direction parallel to the light-emitting surface 22 in a top view is referred to as a midpoint MP5. In the illustrated light-emitting device 1, the lateral direction of the submount 30 and the direction parallel to the light-emitting surface 22 in the top view are in the same direction.

With respect to the plurality of semiconductor laser elements 20, the distance from the midpoint MP4 of the first semiconductor laser element 20A to the midpoint MP5 of the first submount 30A on which this first semiconductor laser element 20A is disposed is equal to the distance from the midpoint MP4 of the second semiconductor laser element 20B to the midpoint MP5 of the second submount 30B on which this second semiconductor laser element 20B is disposed. The term “equal” as used here allows for a difference within ±50 μm. Making these distances equal facilitates the mounting of the first semiconductor laser element 20A and the second semiconductor laser element 20B respectively on the submounts 30 of the same design.

With respect to the plurality of semiconductor laser elements 20, the distance from the midpoint MP4 of the first semiconductor laser element 20A to the midpoint MP2 of the first submount 30A on which this first semiconductor laser element 20A is disposed is equal to the distance from the midpoint MP4 of the second semiconductor laser element 20B to the midpoint MP2 of the second submount 30B on which this second semiconductor laser element 20B is disposed. The term “equal” as used here allows for a difference within ±50 μm. Making these distances equal facilitates the mounting of the first semiconductor laser element 20A and the second semiconductor laser element 20B respectively on the submounts 30 of the same design.

The one or each of the semiconductor laser elements 20 is placed such that the light-emitting surface 22 is included in a region in the vicinity of the side of the outer edge of the upper surface 31A in a top view. In a top view, the light-emitting surface 22 of the one or each of the semiconductor laser elements 20 is placed between the lateral surface 31C of the upper metal member 32B and the lateral surface 31C of the substrate 32A, which face in the same direction.

With respect to the plurality of semiconductor laser elements 20, in a top view, the distance from the first lateral surface 21C1 of the first semiconductor laser element 20A to the lateral surface 31C of the first submount 30A facing in the same direction as the first lateral surface 21C1 is greater, in a top view, than the distance from the first lateral surface 21C1 of the second semiconductor laser element 20B to the lateral surface 31C of the second submount 30B facing in the same direction as the first lateral surface 21C1 by a range from 200 μm to 400 μm.

The protective element 50 is disposed on the one or each of the submounts 30. Here, to distinguish the protective elements 50, the protective element 50 disposed on the first submount 30A is referred to as a first protective element 50A, and the protective element 50 disposed on the second submount 30B is referred to as a second protective element 50B. The plurality of protective elements 50 include one or more first protective elements 50A and one or more second protective elements 50B.

The plurality of submounts 30 include one or more first submounts 30A on which the first semiconductor laser element 20A and the first protective element 50A are disposed, and one or more second submounts 30B on which the second semiconductor laser element 20B and the second protective element 50B are disposed.

In one or each of the submounts 30, the protective element 50 is disposed on the wiring layer 33. Each of the protective elements 50 is disposed in the second region 33B of the wiring layer 33. The first protective element 50A and the second protective element 50B are the protective elements 50 having the same shape. The shape of the first protective element 50A and the shape of the second protective element 50B may be different.

The one or each of the first protective elements 50A is not placed between a first virtual straight line L1 and a second virtual straight line L2. The first virtual straight line L1 passes through and is parallel to the light-emitting surface 22 of the first semiconductor laser element 20A. The second virtual straight line L2 passes through and is parallel to the first lateral surface 21C1 of the first semiconductor laser element 20A in a top view.

A part or all of the one or each of the second protective elements 50B is placed between a third virtual straight line L3 and a fourth virtual straight line L4. The third virtual straight line L3 passes through and is parallel to the light-emitting surface 22 of the second semiconductor laser element 20B. The fourth virtual straight line L4 passes through and is parallel to the first lateral surface 21C1 of the second semiconductor laser element 20B in a top view. The second protective element 50B is placed at a position through which the fourth virtual straight line L4 passes in a top view.

With respect to the one or each of the first semiconductor laser elements 20A, in a top view, the midpoint MP4 of the first semiconductor laser element 20A does not coincide with the midpoint MP5 of the first submount 30A on which this first semiconductor laser element 20A is disposed. With respect to the one or each of the second semiconductor laser elements 20B, in a top view, the midpoint MP4 of the second semiconductor laser element 20B does not coincide with the midpoint MP5 of the second submount 30B on which this second semiconductor laser element 20B is disposed.

In this way, even when at least a part of the second protective element 50B is placed between the third virtual straight line L3 and the fourth virtual straight line L4, the second protective element 50B can be stably mounted on the second submount 30B by shifting the midpoint MP4 without coinciding it with the midpoint MP5. Thus, the submounts 30 of the same design can be respectively used in common for two semiconductor laser elements 20 having mutually different lengths in the resonator direction. Respective use of the submounts 30 in common can contribute to improvement in productivity of the light-emitting device 1.

The one or each of the protective elements 50 is placed in a region having a larger area when the upper surface 31A of the submount 30 is divided into two regions by the virtual straight line SL2 that passes through the midpoint MP1 of the submount 30 and is parallel to the longitudinal direction of the submount 30.

Here, of the two lateral surfaces 21C meeting the light-emitting surface 22 of the semiconductor laser element 20, the lateral surface 21C distanced closer to the protective element 50 is referred to as a second lateral surface 21C2, and the lateral surface 21C distanced farther from the protective element 50 is referred to as a third lateral surface 21C3.

The one or each of the protective elements 50 is placed on the upper surface 31A of the submount 30 in the vicinity of the lateral surface 31C of the submount 30 facing in the same direction as the first lateral surface 21C1 and in the vicinity of the lateral surface 31C of the submount 30 facing in the same direction as the second lateral surface 21C2.

With respect to the one or each of the submounts 30, the distance from the midpoint MP4 of the semiconductor laser element 20 to the lateral surface 31C of the submount 30 facing in the same direction as the third lateral surface 21C3 in the direction parallel to the light-emitting surface 22 is less than or equal to twice the width of the protective element 50. This distance is preferably in a range from 260 μm to 420 μm. Setting the distance to 260 μm or more can ensure heat dissipation to the semiconductor laser element 20, and setting the distance to 420 μm or less can reduce the width of the submount 30 in the direction parallel to the light-emitting surface 22.

With respect to the one or each of the second semiconductor laser elements 20B, the midpoint MP4 of the second semiconductor laser element 20B is separated from the midpoint MP5 of the second submount 30B on which this second semiconductor laser element 20B is disposed by a range from 10 μm to 200 μm in the direction parallel to the light-emitting surface 22 of the second semiconductor laser element 20B in a top view. Separating the midpoint MP4 from the midpoint MP5 by 10 μm or more can achieve a stable mounting of the semiconductor laser element 20 and the protective element 50. Separating the midpoint MP4 from the midpoint MP5 by not exceeding 200 μm can ensure sufficient heat dissipation to the semiconductor laser element 20.

With respect to the one or each of the first semiconductor laser elements 20A, the midpoint MP4 of the first semiconductor laser element 20A is separated from the midpoint MP5 of the first submount 30A on which this first semiconductor laser element 20A is disposed by a range from 10 μm to 200 μm in the direction parallel to the light-emitting surface 22 of the first semiconductor laser element 20A in a top view.

For the first semiconductor laser element 20A and the second semiconductor laser element 20B, the distance from the midpoint MP4 of the semiconductor laser element 20 to the midpoint MP5 of the submount 30 on which this semiconductor laser element 20 is disposed in the direction parallel to the light-emitting surface 22 of the semiconductor laser element 20 is the same. This facilitates placement of the plurality of semiconductor laser elements 20 by arranging the light emission points at equal intervals.

With respect to the plurality of semiconductor laser elements 20, the distance between the first semiconductor laser element 20A and the first protective element 50A disposed on the first submount 30A is greater than the distance between the second semiconductor laser element 20B and the second protective element 50B disposed on the second submount 30B. With respect to the plurality of semiconductor laser elements 20, the distance between the first semiconductor laser element 20A and the first protective element 50A disposed on the first submount 30A is equal to the distance between the second semiconductor laser element 20B and the second protective element 50B disposed on the second submount 30B in the distance in the direction parallel to the light-emitting surface 22 of the semiconductor laser element 20. Mounting the semiconductor laser element 20 and the protective element 50 on the submount 30 in this way allows the submounts 30 of the same design to be respectively used in common for two semiconductor laser elements having mutually different lengths in the resonator direction.

With respect to the one or each of the first submounts 30A, in the resonator direction, the length of the first submount 30A is greater than the sum of the respective lengths of the first semiconductor laser element 20A and the first protective element 50A that are disposed on this first submount 30A in a top view.

With respect to the one or each of the second submounts 30B, in the resonator direction, the length of the second submount 30B is greater than the sum of the respective lengths of the second semiconductor laser element 20B and the second protective element 50B that are disposed on this second submount 30B in a top view. This suppresses the increase in length of the submount 30 in the resonator direction, thus contributing to a reduction in size of the light-emitting device 1.

The plurality of semiconductor laser elements 20 are placed in the internal space of the package 10. The plurality of submounts 30 are placed in the internal space of the package 10. The plurality of semiconductor laser elements 20 are placed on the first upper surface 11A via the submounts 30. The plurality of submounts 30 are placed on the first upper surface 11A.

The plurality of submounts 30 are arranged side by side in a first direction on the first upper surface 11A of the base 11. The plurality of submounts 30 are arranged side by side such that the interval between the submounts 30 disposed adjacent to each other is 300 μm or less. In the illustrated light-emitting device 1, the first direction is the same direction as the positive direction of X or negative direction of X.

The plurality of submounts 30 are arranged side by side in a direction in which the first inner lateral surface 11E1 and the second inner lateral surface 11E2 face each other. The direction in which the two inner lateral surfaces face each other is a direction from one inner lateral surface to the other inner lateral surface. The plurality of submounts 30 are arranged side by side in a direction in which the first lateral surface 11H1 and the second lateral surface 11H2 face each other.

The plurality of semiconductor laser elements 20 are arranged side by side in the first direction on the first upper surface 11A of the base 11. Each of the plurality of semiconductor laser elements 20 is placed on the first upper surface 11A via the submount 30.

The plurality of semiconductor laser elements 20 are placed at equal intervals in the first direction. The term “equal interval” as used here allows for a difference within ±50 μm. The plurality of semiconductor laser elements 20 are placed such that emission points of light emitted from the light-emitting surface 22 are arranged at equal intervals in the first direction. The term “equal interval” as used here allows for a difference within ±50 μm.

The plurality of submounts 30 are arranged at equal intervals in the first direction. The term “equal interval” as used here allows for a difference within ±50 μm. In each of the submounts 30, the midpoint MP1 of the submount 30 is separated from the midpoint MP2 in the first direction. This facilitates the arrangement of the plurality of semiconductor laser elements 20 at equal intervals in the first direction.

In each of the semiconductor laser elements 20, the midpoint MP4 of the semiconductor laser element 20 is separated in the first direction from the midpoint MP5 of the submount 30 on which this semiconductor laser element 20 is disposed.

In a top view, in the first direction, the distance from the first lateral surface 11H1 to the submount 30 disposed at a position closest to the first lateral surface 11H1 among the plurality of submounts 30 is greater than the distance between the submounts 30 disposed adjacent to each other and smaller than the width of the submount 30. Placing the submount 30 in this way allows more semiconductor laser elements 20 to be placed in the internal space of the package 10.

In a top view, in the first direction, the distance from the second lateral surface 11H2 the submount 30 disposed at a position closest to the second lateral surface 11H2 among the plurality of submounts 30 is greater than the distance between the submounts 30 disposed adjacent to each other and smaller than the width of the submount 30. Placing the submount 30 in this way allows more semiconductor laser elements 20 to be placed in the internal space of the package 10.

In a top view, in the first direction, the distance from the first lateral surface 11H1 to the submount 30 disposed at a position closest to the first lateral surface 11H1 among the plurality of submounts 30 is different from the distance from the second lateral surface 11H2 to the submount 30 disposed at a position closest to the second lateral surface 11H2 among the plurality of submounts 30. Placing the submount 30 in this way allows the plurality of semiconductor laser elements 20 to be placed in a centrosymmetric manner with respect to the first direction in the internal space of the package 10.

In a top view, in the second direction perpendicular to the first direction, the distance from the lateral surface 31C of the first submount 30A facing in the same direction as the first lateral surface 21C1 of the first semiconductor laser element 20A to the inner lateral surface 11E of the base 11 facing in the first lateral surface 21C1 is smaller than the distance obtained by adding 200 μm to the difference between the lengths of the first semiconductor laser element 20A and the second semiconductor laser element 20B in the resonator direction. When the first submount 30A is placed in this way, if a submount is adopted in which the second protective element 50B is separated from the second semiconductor laser element 20B in the resonator direction, the light-emitting surface 22 of the first semiconductor laser element 20A and the light-emitting surface 22 of the second semiconductor laser element 20B are largely deviated in the resonator direction. Therefore, as in the light-emitting device 1, there is an additional advantage in respectively using the submounts 30 of the same design in common for the first semiconductor laser element 20A and the second semiconductor laser element 20B.

This distance is less than or equal to 100 μm for the two semiconductor laser elements 20, among the plurality of semiconductor laser elements 20, having the maximum distance from the light-emitting surface 22 to the light-emitting surface 22 in the second direction. Alternatively, this distance can be 50 μm or less. Alternatively, this distance can be 30 μm or less. The light-emitting surfaces 22 of the plurality of semiconductor laser elements 20 are positioned so as not to deviate largely in the second direction.

Each of the plurality of semiconductor laser elements 20 emits light in the second direction from the light-emitting surface 22. With respect to the plurality of semiconductor laser elements 20, the light emitted from the light-emitting surface 22 and traveling along the optical axis is the light traveling in the second direction. Each of the semiconductor laser elements 20 emits light from the light-emitting surface 22 in the FFP in which the second direction is the optical axis.

The light emitted from the plurality of semiconductor laser elements 20 can be regarded as a collection of light emitted from each of the semiconductor laser elements 20. Here, the light emitted from each semiconductor laser element 20 is referred to as a partial light, as opposed to the light emitted from the plurality of semiconductor laser elements 20. The light emitted from the plurality of semiconductor laser elements 20 is constituted by a plurality of partial lights.

In the light-emitting device 1, one or more reflective members 40 are placed in the internal space of the package 10. The one or more reflective members 40 are placed on the first upper surface 11A. One reflective member 40 can be placed corresponding to one semiconductor laser element 20. In this case, the light-reflective surface 41B of one reflective member 40 can be irradiated with a main portion light of one partial light. In addition, in this case, the light-reflective surface 41B of one reflective member 40 is not irradiated with the main portion lights of two partial lights.

One or more reflective members 40 reflect light emitted from the plurality of semiconductor laser elements 20. Light emitted from the plurality of semiconductor laser elements 20 is reflected upward by the light-reflective surface 41B of the one or more reflective members 40. The light traveling along the optical axis in each partial light is emitted from the light-emitting surface 22, reflected by the light-reflective surface 41B, and travels in a direction perpendicular to the first upper surface 11A.

A plurality of points P1 constituted by points P1, at which one or more reflective members 40 are irradiated with light traveling along the optical axis in each of the plurality of partial lights, are positioned line-symmetrically in a top view in the first direction about the virtual straight line SL3 that passes through the midpoint of both ends of the base 11 in the first direction and is perpendicular to the first direction. This allows the plurality of partial lights to be emitted from the light-emitting device 1 in a similar line-symmetrical arrangement, facilitating optical design using the light emitted from the light-emitting device 1.

In a top view, in the first direction, the distance from the midpoint of both ends of the base 11 in the first direction to the midpoint of both ends EP1 in the first direction of the one or more reflective members 40 is smaller than the distance from the midpoint of both ends of the base 11 in the first direction to the midpoint of both ends EP2 in the first direction of the plurality of submounts 30. Designing the mounting position based on the reflective member 40, instead of the submount 30, with respect to the center of the package 10 in the first direction facilitates the optical design using the light emitted from the light-emitting device 1.

In the light-emitting device 1, a plurality of wirings 60 are placed in the internal space of the package 10. The plurality of wirings 60 include two or more wirings 60 for electrically connecting the plurality of semiconductor laser elements 20 to the base 11. The plurality of wirings 60 include two or more wirings 60 for electrically connecting the plurality of protective elements 50 to the base 11. Provision of the plurality of wirings 60 enables electric power to be supplied from an external power source to the plurality of semiconductor laser elements 20 through the base 11.

The plurality of wirings 60 include two or more wirings 60 for electrically connecting the one or more first semiconductor laser elements 20A to the base 11. The plurality of wirings 60 include two or more wirings 60 for electrically connecting the one or more second semiconductor laser elements 20B to the base 11.

The plurality of wirings 60 include the wiring 60 bonded to the first wiring portion 12A1. The plurality of wirings 60 include the wiring 60 bonded to a first wiring portion 12A1 provided on the first inner lateral surface 11E1 side and a wiring 60 bonded to the first wiring portion 12A1 provided on the second inner lateral surface 11E2 side. The plurality of wirings 60 include a wiring 60 not bonded to the first wiring portion 12A1.

The first wiring portion 12A1 provided on the upper surface 11G of a first step portion 11F1 is an example of the first wiring portion 12A1 provided on the first inner lateral surface 11E1 side, and the first wiring portion 12A1 provided on the upper surface 11G of a second step portion 11F2 is an example of the first wiring portion 12A1 provided on the second inner lateral surface 11E2 side.

In the light-emitting device 1, the optical member 70 is placed on an optical path of light emitted from the plurality of semiconductor laser elements 20. The optical member 70 is fixed to the package 10. The optical member 70 is placed outside the package 10. The optical member 70 is bonded to the upper surface 14A.

The light emitted from the plurality of semiconductor laser elements 20 is imparted an optical action and is emitted from the optical member 70. For example, each of the plurality of partial lights is collimated through the lens surface 71D and is emitted from the optical member 70 as the collimated light. Also, for example, each of the plurality of partial lights is emitted from the optical member 70 as wavelength-converted light.

With respect to each of the plurality of partial lights, the light passing through the optical axis passes through the optical axis OA of the lens surface 71D of the optical member 70. With respect to the plurality of partial lights, the main portion light in the partial lights respectively pass through lens surfaces 71D.

The optical member 70 is placed such that the coupling direction is the same direction as the first direction. A plurality of optical axes OA constituted by the optical axes OA of respective lens surfaces of the plurality of lens surfaces 71D are positioned line-symmetrically in a top view in the first direction about the virtual straight line SL3 that passes through the midpoint of both ends in the first direction of the base 11 and is perpendicular to the first direction in a top view. Alternatively, the same can be said by replacing “optical axes OA” with “vertices”. This facilitates the optical design using the light emitted from the light-emitting device 1.

In a top view, in the first direction, the distance from the midpoint of both ends of the base 11 in the first direction to the midpoint of the vertices of both lens surfaces 71D in the plurality of lens surfaces 71D arranged in the first direction is smaller than the distance from the midpoint of both ends of the base 11 in the first direction to the midpoint of both ends EP2 of the plurality of submounts 30 in the first direction. Designing the mounting position based on the optical member 70, instead of the submount 30, with respect to the center of the package 10 in the first direction facilitates the optical design using the light emitted from the light-emitting device 1.

### Second Embodiment

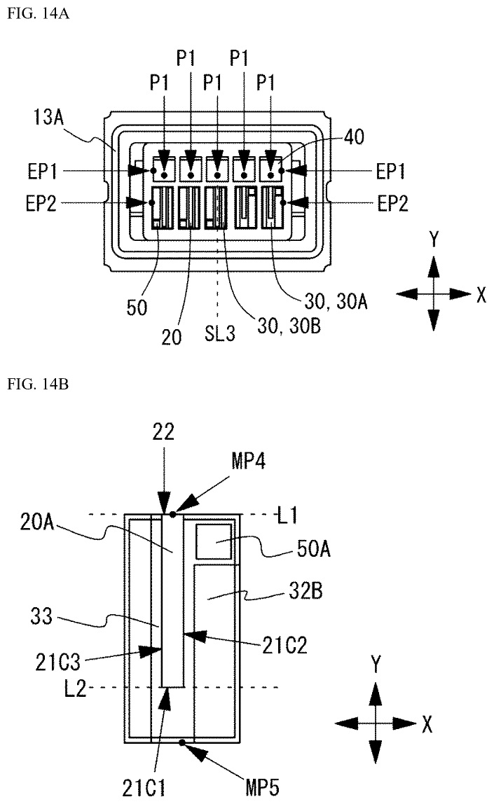

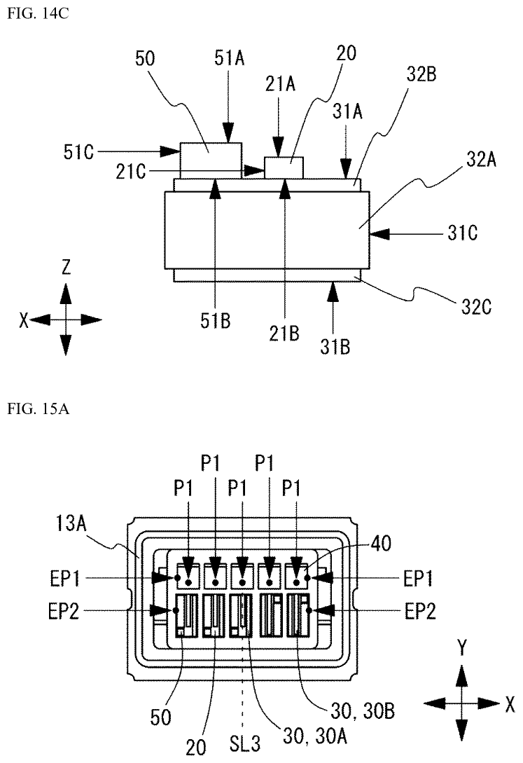

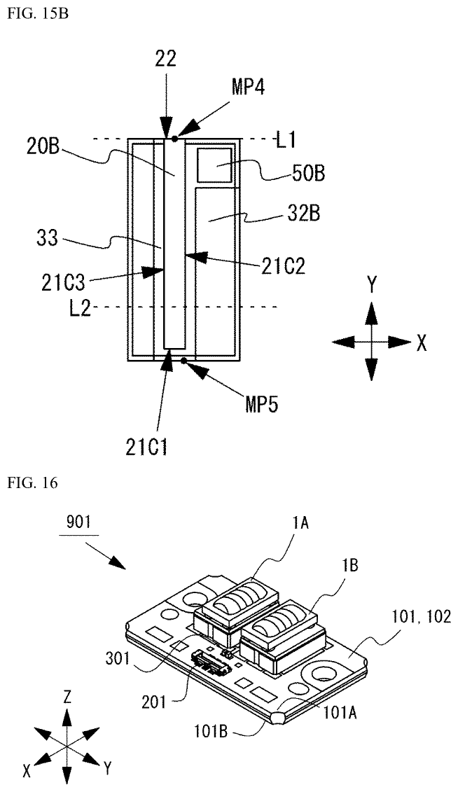

A light-emitting device 2 according to the second embodiment will now be described. FIGS. 1, 2, and 6 to 15B are schematic drawings for explaining an exemplary form of the light-emitting device 2. FIG. 1 is a schematic perspective view of the light-emitting device 2. FIG. 2 is a schematic side view of the light-emitting device 2. FIG. 14A is a schematic top view for explaining a first example of the internal structure of the light-emitting device 2. FIG. 14B is a schematic top view illustrating a state in which the first semiconductor laser element 20A and the first protective element 50A are disposed on the first submount 30A. FIG. 14C is a schematic side view illustrating a state in which the semiconductor laser element 20 and the protective element 50 illustrated in FIGS. 14B and 15B are disposed on the submount 30. FIG. 15A is a schematic top view for explaining a second example of the internal structure of the light-emitting device 2. FIG. 15B is a schematic top view illustrating a state in which the second semiconductor laser element 20B and the second protective element 50B are disposed on the second submount 30B. FIG. 6 is a schematic top view of the submount 30. FIG. 7A is a schematic top view illustrating a state in which the first semiconductor laser element 20A and the first protective element 50A are disposed on the first submount 30A in the internal structure of the second example. FIG. 7B is a schematic top view illustrating a state in which the second semiconductor laser element 20B and the second protective element 50B are disposed on the second submount 30B in the internal structure of the first example. FIG. 8 is a schematic side view illustrating a state in which the semiconductor laser element 20 and the protective element 50 illustrated in FIGS. 7A and 7B are disposed on the submount 30. FIG. 9 is a schematic perspective view of the package 10. FIG. 10 is a schematic cross-sectional view of the package 10A taken along a cross-sectional line X-X in FIG. 9. FIG. 11 is a schematic top view of the base 11. FIG. 12 is a schematic bottom view of the base 11. FIG. 13 is a schematic cross-sectional view of the base 11 taken along a cross-sectional line XIII-XIII in FIG. 11.

All of the above description of the light-emitting device 1 and the components of the first embodiment is also applicable to the description of the light-emitting device 2, excluding the contents that can be regarded as being contradictory to the drawings of FIGS. 1, 2, and 6 to 15B related to the light-emitting device 2. All non-contradictory contents will not be repeated here in order to avoid duplication.

### Light-Emitting Device 2

In the light-emitting device 2, of the first submount 30A and the second submount 30B, the protective element 50 disposed on one submount 30 is disposed on the first lateral surface 21C1 side of the semiconductor laser element 20, and the protective element 50 disposed on the other submount 30 is disposed on the light-emitting surface 22 side of the semiconductor laser element 20.

In the example of FIG. 14A, the first protective element 50A disposed on the first submount 30A is disposed on the light-emitting surface 22 side of the first semiconductor laser element 20A, and the second protective element 50B disposed on the second submount 30B is disposed on the first lateral surface 21C1 side of the second semiconductor laser element 20B. In the example of FIG. 15A, the first protective element 50A disposed on the first submount 30A is disposed on the first lateral surface 21C1 side of the first semiconductor laser element 20A, and the second protective element 50B disposed on the second submount 30B is disposed on the light-emitting surface 22 side of the second semiconductor laser element 20B.

In the example of FIG. 14A, in a top view, one or each of the first protective elements 50A is placed between the first virtual straight line L1 that passes through and is parallel to the light-emitting surface 22 of the first semiconductor laser element 20A, and the second virtual straight line L2 that passes through and is parallel to the first lateral surface 21C1 of the first semiconductor laser element 20A.

In the example of FIG. 14A, the one or each of the first protective elements 50A is placed on the upper surface 31A of the first submount 30A in the vicinity of the lateral surface 31C of the first submount 30A which faces in the same direction as the light-emitting surface 22, and in the vicinity of the lateral surface 31C of the first submount 30A which faces in the same direction as the third lateral surface 21C3.

In the example of FIG. 15A, the one or each of the second protective elements 50B is placed on the upper surface 31A of the second submount 30B in the vicinity of the lateral surface 31C of the second submount 30B which faces in the same direction as the light-emitting surface 22, and in the vicinity of the lateral surface 31C of the second submount 30B which faces in the same direction as the third lateral surface 21C3.

In the example of FIG. 14A, with respect to the plurality of semiconductor laser elements 20, the distance between the first semiconductor laser element 20A and the first protective element 50A which are disposed on the first submount 30A is equal to the distance between the second semiconductor laser element 20B and the second protective element 50B which are disposed on the second submount 30B.

The plurality of submounts 30 are arranged at equal intervals in the first direction, except for the first submount 30A and the second submount 30B which are disposed adjacent to each other. The distance between the first submount 30A and the second submount 30B disposed adjacent to each other is greater than the distance between the first submounts 30A disposed adjacent to each other. The distance between the first submount 30A and the second submount 30B disposed adjacent to each other is greater than the distance between the second submounts 30B disposed adjacent to each other.

In each of the first submounts 30A, the midpoint MP1 of the first submount 30A is separated from the midpoint MP2 in the first direction. In each of the second submounts 30B, the midpoint MP1 of the second submount 30B is separated from the midpoint MP2 in the direction opposite to the first direction. In the example of FIG. 14A, the first direction is the same direction as the negative direction of X, while in the example of FIG. 15A, the first direction is the same direction as the positive direction of X.

In each of the first semiconductor laser elements 20A, the midpoint MP4 of the first semiconductor laser element 20A is separated in the first direction from the midpoint MP5 of the first submount 30A on which this first semiconductor laser element 20A is disposed. In each of the second semiconductor laser elements 20B, the midpoint MP4 of the second semiconductor laser element 20B is separated in the direction opposite to the first direction from the midpoint MP5 of the second submount 30B on which this second semiconductor laser element 20B is disposed. In the example of FIG. 14A, the first direction is the same direction as the negative direction of X, while in the example of FIG. 15A, the first direction is the same direction as the positive direction of X.

In a top view, in the first direction, the distance from the first lateral surface 11H1 to the submount 30 disposed at a position closest to the first lateral surface 11H1 among the plurality of submounts 30 is equal to the distance from the second lateral surface 11H2 to the submount 30 disposed at a position closest to the second lateral surface 11H2 among the plurality of submounts 30. Placing the submount 30 in this way allows the plurality of semiconductor laser elements 20 to be placed in a centrosymmetric manner with respect to the first direction in the internal space of the package 10.

### Third Embodiment

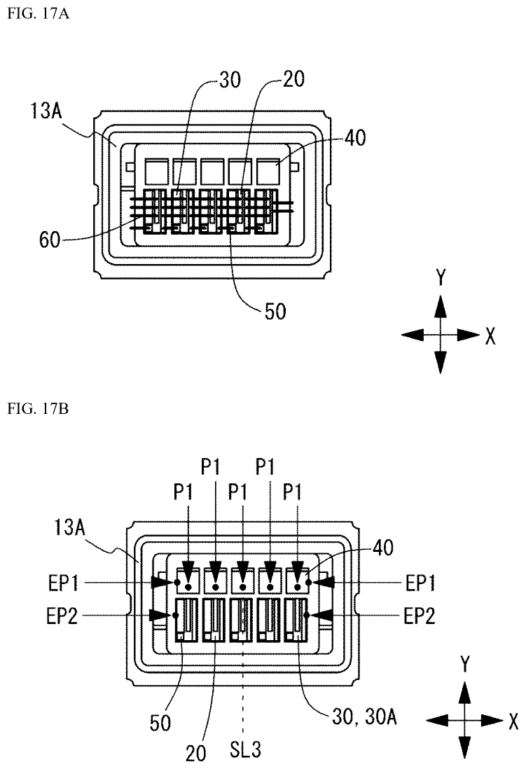

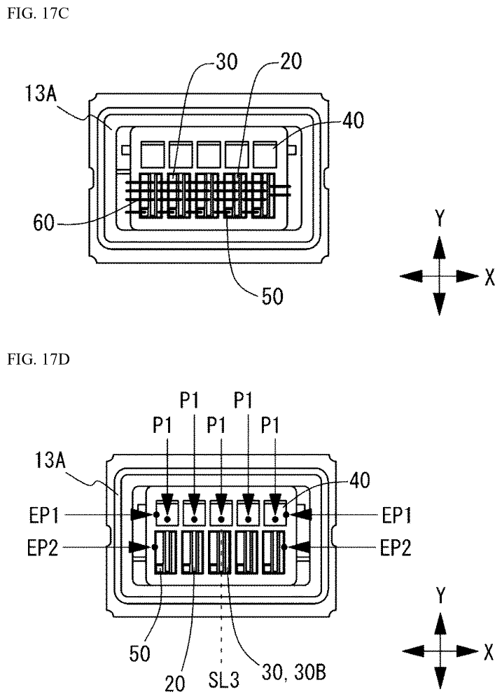

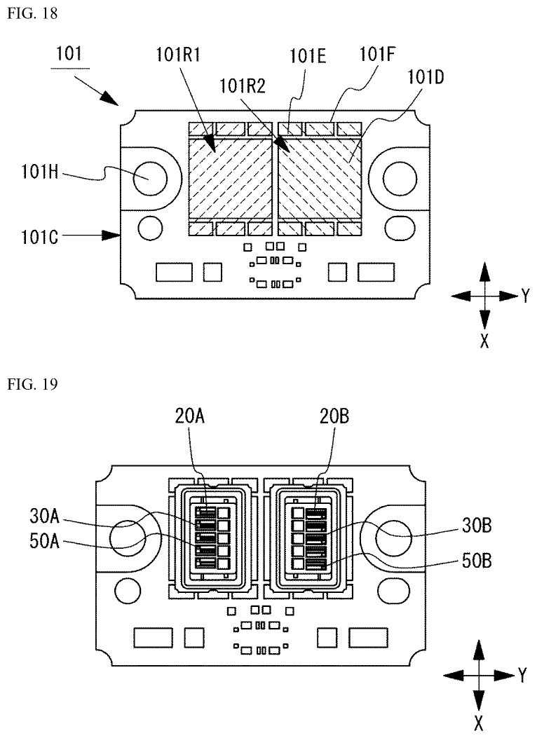

A light-emitting module 901 according to a third embodiment will be described. FIGS. 1 to 3, 6 to 13, and 16 to 19 are schematic drawings for explaining an exemplary form of the light-emitting module 901. FIG. 16 is a schematic perspective view of the light-emitting module 901. FIG. 1 is a schematic perspective view of the first light-emitting device 1A and the second light-emitting device 1B. FIG. 2 is a schematic side view of the first light-emitting device 1A and the second light-emitting device 1B. FIG. 3 is a schematic cross-sectional view of the first light-emitting device 1A and the second light-emitting device 1B taken along a cross-sectional line III-III in FIG. 1. FIG. 17A is a schematic top view for explaining an internal structure of the first light-emitting device 1A. FIG. 17B is a schematic top view illustrating a state in which the wirings 60 are removed from FIG. 17A. FIG. 17C is a schematic top view for explaining an internal structure of the second light-emitting device 1B. FIG. 17D is a schematic top view illustrating a state in which the wirings 60 are removed from FIG. 17C. FIG. 6 is a schematic top view of the submount 30. FIG. 7A is a schematic top view illustrating a state in which the first semiconductor laser element 20A and the first protective element 50A are disposed on the first submount 30A. FIG. 7B is a schematic top view illustrating a state in which the second semiconductor laser element 20B and the second protective element 50B are disposed on the second submount 30B. FIG. 8 is a schematic side view illustrating a state in which the semiconductor laser element 20 and the protective element 50 are disposed on the submount 30. FIG. 9 is a schematic perspective view of the package 10. FIG. 10 is a schematic cross-sectional view of the package 10 taken along a cross-sectional line X-X in FIG. 9. FIG. 11 is a schematic top view of the base 11. FIG. 12 is a schematic bottom view of the base 11. FIG. 13 is a schematic cross-sectional view of the base 11 taken along a cross-sectional line XIII-XIII in FIG. 11. FIG. 18 is a schematic top view of a wiring substrate 101. In FIG. 18, a first connection region 101R1 and a second connection region 101R2 are indicated by hatching. FIG. 19 is a schematic top view for explaining an internal structure of the first light-emitting device 1A and the second light-emitting device 1B in the light-emitting module 901.

The light-emitting module 901 includes a plurality of components. A plurality of components provided in the light-emitting module 901 include the first light-emitting device 1A, the second light-emitting device 1B, the wiring substrate 101, a connector 201, and a thermistor 301.

The light-emitting module 901 may also include a component other than these components. For example, the light-emitting module 901 may include a light-emitting device different from the first light-emitting device 1A and the second light-emitting device 1B. The light-emitting module 901 need not include some of the plurality of components described above.

All of the above description of the light-emitting device 1 and the components of the first embodiment is also applicable to the description of the first light-emitting device 1A and the second light-emitting device 1B, excluding the contents that can be regarded as being contradictory to the drawings of FIGS. 1 to 3, 6 to 13, and 16 to 19 related to the light-emitting module 901. All non-contradictory contents will not be repeated here in order to avoid duplication.

First Light-Emitting Device 1A and Second Light-Emitting Device 1B The first light-emitting device 1A and the second light-emitting device 1B both include a plurality of components. The plurality of components provided in each of the light-emitting devices include the package 10, one or more semiconductor laser elements 20, one or more submounts 30, one or more reflective members 40, one or more protective elements 50, the plurality of wirings 60, and the optical member 70.

The plurality of semiconductor laser elements 20 provided in the first light-emitting device 1A include the plurality of first semiconductor laser element 20A. The plurality of semiconductor laser elements 20 provided in the second light-emitting device 1B include the plurality of second semiconductor laser element 20B. The first light-emitting device 1A includes the plurality of first submounts 30A, and the second light-emitting device 1B includes the plurality of second submounts 30B. The first light-emitting device 1A includes the plurality of first protective elements 50A, and the second light-emitting device 1B includes the plurality of second protective elements 50B.

The plurality of semiconductor laser elements 20 provided in the first light-emitting device 1A are constituted by the plurality of first semiconductor laser elements 20A. Thus, the first light-emitting device 1A does not include the second semiconductor laser elements 20B. The plurality of semiconductor laser elements 20 provided in the second light-emitting device 1B are constituted by the plurality of second semiconductor laser elements 20B. The second light-emitting device 1B does not include the first semiconductor laser elements 20A. The first light-emitting device 1A may include the second semiconductor laser elements 20B. The second light-emitting device 1B may include the first semiconductor laser elements 20A.

The first light-emitting device 1A and the second light-emitting device 1B each include the package 10 of the same outer shape. The first light-emitting device 1A and the second light-emitting device 1B each include the base 11 of the same outer shape.

The quantity of the first semiconductor laser elements 20A provided in the first light-emitting device 1A is equal to the quantity of the second semiconductor laser elements 20B provided in the second light-emitting device 1B. Respectively using the submounts 30 of the same shape in common for the packages 10 of the same outer shape facilitates mounting of the same quantity of semiconductor laser elements 20 in the first light-emitting device 1A and the second light-emitting device 1B.

### Wiring Substrate 101

The wiring substrate 101 has an upper surface 101A, a lower surface 101B, and one or more lateral surfaces 101C. The wiring substrate 101 has a plate-like shape. The outer edge shape of the wiring substrate 101 in a top view is rectangular. This rectangular shape can be a rectangular shape with long sides and short sides. In the package 10 illustrated by the drawings, a short-side direction of the rectangular shape is the same direction as the X direction, and a long-side direction is the same direction as the Y direction.

The wiring substrate 101 includes heat dissipation portions 101D, electrode portions 101E, and an insulating portion 101F. The heat dissipation portion 101D functions as a heat dissipation path for heat generated from other components mounted on the wiring substrate 101. The electrode portion 101E is electrically connected to the other components mounted on the wiring substrate 101.

The insulating portion 101F insulates the heat dissipation portion 101D and the electrode portion 101E. The insulating portion 101F is provided to insulate electrical connection between the heat dissipation portion 101D and the electrode portion 101E in the wiring substrate 101.

The wiring substrate 101 is provided with one or more through holes 101H. The one or more through holes 101H include a through hole 101H used for fixing the wiring substrate 101 to another member (component). For example, a screw is fitted into the through hole 101H to fix the wiring substrate 101 to another member. The one or more through holes 101H include the through hole 101H used for determining positions when fixing the wiring substrate 101 to another member.

As the main material of the heat dissipation portion 101D, a metal material can be used. For example, as the main material of the heat dissipation portion 101D, a single-component metal, such as Cu, Ag, Al, Ni, Rh, Au, Ti, Pt, Pd, Mo, Cr, and W, or an alloy containing any of these metals can be used. The heat dissipation portion 101D is preferably made of a material having excellent heat dissipation. The heat dissipation portion 101D can be made by containing 95 mass % or more of copper.

As the main material of the electrode portion 101E, a metal material can be used. For example, as the main material of the electrode portion 101E, a single-component metal, such as Cu, Ag, Al, Ni, Rh, Au, Ti, Pt, Pd, Mo, Cr, and W, or an alloy containing any of these metals can be used.

The insulating portion 101F is made of an insulating material. For example, polyimide can be used as the main material of the insulating portion 101F. Also, for example, as the main material of the insulating portion 101F, glass epoxy obtained by impregnating one or more glass cloths with a thermosetting insulating resin, such as an epoxy resin, and curing the thermosetting insulating resin, a liquid crystal polymer, or the like can be used.

### Connector 201

The connector 201 has an insertion port into which a connector cable is inserted.

### Thermistor 301

The thermistor 301 can be used as an element for measuring temperatures.

### Light-Emitting Module 901

In the light-emitting module 901, the first light-emitting device 1A and the second light-emitting device 1B are mounted on the wiring substrate 101. The wiring substrate 101 can be regarded as an example of a mounting substrate on which the first light-emitting device 1A and the second light-emitting device 1B are mounted.

Both of the first light-emitting device 1A and the second light-emitting device 1B are placed on the upper surface 101A. Each of the first light-emitting device 1A and the second light-emitting device 1B is bonded to the electrode portion 101E via an electrically conductive bonding material. Thus, the first light-emitting device 1A and the second light-emitting device 1B are electrically connected to the wiring substrate 101.

The wiring substrate 101 includes a first connection region 101R1 and a second connection region 101R2 each including the electrode portion 101E. The electrode portion 101E included in the first connection region 101R1 does not overlap with the electrode portion 101E included in the second connection region 101R2.

In a top view, the first connection region 101R1 and the second connection region 101R2 have the same shape. Each region has a rectangular shape in a top view.

Either the first light-emitting device 1A or the second light-emitting device 1B is placed in the first connection region 101R1. Either the first light-emitting device 1A or the second light-emitting device 1B is placed in the second connection region 101R2. The first light-emitting device 1A may also be placed in each of the first connection region 101R1 and the second connection region 101R2. In addition, the light-emitting device 1 or the light-emitting device 2 described above may be placed in the first connection region 101R1 or the second connection region 101R2. In the illustrated light-emitting module 901, the first light-emitting device 1A is placed in the first connection region 101R1, and the second light-emitting device 1B is placed in the second connection region 101R2.

The first connection region 101R1 can be defined as a minimum rectangular region including the electrode portion 101E bonded to the light-emitting device placed in the first connection region 101R1 via the electrode portion 101E sectioned by the insulating portion 101F in a top view. The second connection region 101R2 can be defined as a minimum rectangular region including the electrode portion 101E bonded to the light-emitting device placed in the second connection region 101R2 via the electrode portion 101E sectioned by the insulating portion 101F in a top view. The two hatched regions illustrated in FIG. 18 indicate the first connection region 101R1 and the second connection region 101R2 in accordance with this definition.

Alternatively, the first connection region 101R1 may be defined as a minimum rectangular region including a region bonded to the light-emitting device placed in the first connection region 101R1, and the second connection region 101R2 may be defined as a minimum rectangular region including a region bonded to the light-emitting device placed in the second connection region 101R2.

On the wiring substrate 101, the first connection region 101R1 and the second connection region 101R2 are arranged side by side. The first connection region 101R1 and the second connection region 101R2 having the same shape are arranged side by side in one direction and the identical orientation.

In the light-emitting module 901, the first light-emitting device 1A and the second light-emitting device 1B are placed on the wiring substrate 101 such that the first direction is perpendicular to the direction in which the first connection region 101R1 and the second connection region 101R2 are arranged.

In the light-emitting module 901, the first light-emitting device 1A and the second light-emitting device 1B are oriented 180 degrees different from each other in a top view. The first light-emitting device 1A is placed such that the reflective member 40 is located closer to the second light-emitting device 1B than the first semiconductor laser element 20A in the first light-emitting device 1A. The second light-emitting device 1B is placed such that the reflective member 40 is located closer to the first light-emitting device 1A than the second semiconductor laser element 20B in the second light-emitting device 1B.

Because the plurality of irradiation points P1 or the plurality of optical axes OA are arranged line-symmetrically about the virtual straight line SL3, the partial lights can be aligned and emitted even when the first light-emitting device 1A and the second light-emitting device 1B are oriented 180 degrees different from each other. That is, in either the case in which the first light-emitting device 1A and the second light-emitting device 1B are mounted in the same orientation or the case in which they are mounted facing each other, the emission position of the light in the X direction can be aligned, thus reducing a deviation in the light emitting position.

In this way, in the form of the light-emitting module in which a plurality of light-emitting devices is mounted on the mounting substrate, even when two semiconductor laser elements included in one light-emitting device have mutually different lengths in the resonator direction, or even when the semiconductor laser elements included in one of the light-emitting devices have a length in the resonator direction different from a length in the resonator direction of the semiconductor laser elements included in another light-emitting device, the submounts having the same design can respectively be used in common.

In addition, the advantage of respectively using the submounts in common is not limited to the form of the light-emitting module, but can be enjoyed by any practitioner who manufactures or assigns a plurality of light-emitting devices including the first light-emitting device 1A and the second light-emitting device 1B. At this time, the first light-emitting device 1A and the second light-emitting device 1B may be assigned to the same consumer or may be assigned to different consumers. In addition, the plurality of light-emitting devices manufactured or assigned by the practitioner may include the light-emitting device 1 and the light-emitting device 2, the light-emitting device 1 and the first light-emitting device 1A, the light-emitting device 1 and the second light-emitting device 1B, the light-emitting device 2 and the first light-emitting device 1A, or the light-emitting device 2 and the second light-emitting device 1B.

Although the embodiments according to the present invention have been described above, the light-emitting device and the light-emitting module according to the present invention are not strictly limited to the light-emitting device or the light-emitting module of the embodiments. In other words, the present invention can be achieved without being limited to the outer shape or the structure of the light-emitting device or the light-emitting module disclosed in the embodiments. The present invention can be applied without requiring all the components being provided. For example, in a case in which some of the components of the light-emitting device or the light-emitting module disclosed in the embodiments are not stated in the scope of the claims, the degree of freedom in design such as substitutions, omissions, shape modifications, and material changes is admitted for those components by those skilled in the art, and then specified that the invention stated in the scope of the claims is applied thereto.

The light-emitting device and the light-emitting module described in the embodiments can be used in a projector. That is, the projector can be said to be one application to which the present disclosure is applied. Note that the present disclosure is not limited thereto, and can be used in various applications, such as lighting, exposure, on-vehicle headlights, head-mounted displays and backlights of other displays, and the like.

What is claimed is:

1. A light-emitting device comprising:
a plurality of semiconductor laser elements including a first semiconductor laser element and a second semiconductor laser element each having a light-emitting surface and a first lateral surface opposite to the light-emitting surface, the second semiconductor laser element having a length greater than a length of the first semiconductor laser element in a resonator direction that is perpendicular to the light-emitting surface of a corresponding one of the first semiconductor laser element and the second semiconductor laser element;
a plurality of protective elements including a first protective element and a second protective element; and
a plurality of submounts including a first submount and a second submount, the first semiconductor laser element and the first protective element being disposed on the first submount, and the second semiconductor laser element and the second protective element being disposed on the second submount, each of the first submount and the second submount including a mounting surface on which a wiring layer is provided, the wiring layer including
a first region on which a corresponding one of the first semiconductor laser element and the second semiconductor laser element is disposed, and
a second region on which a corresponding one of the first protective element and the second protective element is disposed, wherein
in a top view, the first protective element is not placed between a first virtual straight line and a second virtual straight line, the first virtual straight line passing through and being parallel to the light-emitting surface of the first semiconductor laser element, and the second virtual straight line passing through and being parallel to the first lateral surface of the first semiconductor laser element,
in the top view, a part or all of the second protective element is placed between a third virtual straight line and a fourth virtual straight line, the third virtual straight line passing through and being parallel to the light-emitting surface of the second semiconductor laser element, and the fourth virtual straight line passing through and being parallel to the first lateral surface of the second semiconductor laser element,
in the top view, a midpoint of a width of the light-emitting surface of the first semiconductor laser element does not coincide with a midpoint of a width of the first submount in a direction parallel to the light-emitting surface of the first semiconductor laser element, and
in the top view, a midpoint of a width of the light-emitting surface of the second semiconductor laser element does not coincide with a midpoint of a width of the second submount in a direction parallel to the light-emitting surface of the second semiconductor laser element.

2. The light-emitting device according to claim 1, wherein
the fourth virtual straight line passes through the second protective element in the top view.

3. The light-emitting device according to claim 1, wherein
a length of the first submount is greater than a sum of a length of the first semiconductor laser element and a length of the first protective element in the resonator direction in the top view, and
a length of the second submount is smaller than a sum of a length of the second semiconductor laser element and a length of the second protective element in the resonator direction in the top view.

4. The light-emitting device according to claim 1, wherein
the midpoint of the width of the light-emitting surface of the first semiconductor laser element is separated from the midpoint of the width of the first submount by a range from 10 μm to 200 μm in the direction parallel to the light-emitting surface of the first semiconductor laser element in the top view, and
the midpoint of the width of the light-emitting surface of the second semiconductor laser element is separated from the midpoint of the width of the second submount by a range from 10 μm to 200 μm in the direction parallel to the light-emitting surface of the second semiconductor laser element in the top view.

5. The light-emitting device according to claim 1, wherein
the plurality of semiconductor laser elements are respectively disposed on the plurality of submounts, and
the plurality of submounts are arranged side by side such that an interval between adjacent ones of the plurality of submounts is 300 μm or less.

6. The light-emitting device according to claim 1, further comprising
a base having a first upper surface, a second upper surface located above the first upper surface, and a plurality of inner lateral surfaces located between the first upper surface and the second upper surface, wherein
the plurality of submounts are arranged side by side in a first direction on the first upper surface,
the plurality of inner lateral surfaces include a first inner lateral surface and a second inner lateral surface facing each other in the first direction, and
in the top view, in the first direction, a distance from the first inner lateral surface to one of the plurality of submounts disposed at a position closest to the first inner lateral surface is different from a distance from the second inner lateral surface to one of the plurality of submounts disposed at a position closest to the second inner lateral surface.

7. The light-emitting device according to claim 1, further comprising:
one or more reflective members configured to reflect light emitted from the plurality of semiconductor laser elements; and
a base having a first upper surface on which the plurality of submounts and the one or more reflective members are placed, wherein
the plurality of submounts are arranged side by side in the first direction on the first upper surface, and
in the top view, in the first direction, a distance from a midpoint between both ends of the base in the first direction to a midpoint between both ends of the one or more reflective members in the first direction is smaller than the distance from the midpoint between both ends of the base in the first direction to a midpoint between both ends of the plurality of submounts in the first direction.

8. The light-emitting device according to claim 7, wherein
light emitted from the plurality of semiconductor laser elements is constituted by a plurality of partial lights emitted from the plurality of semiconductor laser elements, and
a plurality of points at which the one or more reflective members are irradiated with light traveling along an optical axis of each of the plurality of partial lights are arranged line-symmetrically in the first direction about a virtual straight line that passes through the midpoint between both ends of the base in the first direction and is perpendicular to the first direction in the top view.

9. A light-emitting module comprising:
a first light-emitting device including
a plurality of first semiconductor laser elements each having a light-emitting surface and a first lateral surface opposite to the light-emitting surface,
a plurality of first protective elements, and
a plurality of first submounts each including a first mounting surface on which a first wiring layer is provided, the first wiring layer including a first region and a second region, the first region being a region on which a corresponding one of the first semiconductor laser elements is disposed, and the second region being a region on which a corresponding one of the first protective elements is disposed;
a second light-emitting device including
a plurality of second semiconductor laser elements each having a light-emitting surface and a second lateral surface opposite to the light-emitting surface,
a plurality of second protective elements, and
a plurality of second submounts each including a second mounting surface on which a second wiring layer is provided, the second wiring layer including a first region and a second region, the first region being a region on which a corresponding one of the second semiconductor laser elements is disposed, and the second region being a region on which a corresponding one of the second protective elements is disposed; and
a mounting substrate on which the first light-emitting device and the second light-emitting device are mounted, wherein
a shape of the first wiring layer of each of the first submounts when viewed from a direction perpendicular to the first mounting surface is identical to a shape of the second wiring layer of each of the second submounts when viewed from a direction perpendicular to the second mounting surface,
in a top view, each of the first protective elements is not placed between a first virtual straight line and a second virtual straight line, the first virtual straight line passing through and being parallel to the light-emitting surface of a corresponding one of the first semiconductor laser elements, and the second virtual straight line passing through and being parallel to the first lateral surface of the corresponding one of the first semiconductor laser elements,
in the top view, a part or all of each of the second protective elements is placed between a third virtual straight line and a fourth virtual straight line, the first virtual straight line passing through and being parallel to the light-emitting surface of a corresponding one of the second semiconductor laser elements, and the fourth virtual straight line passing through and being parallel to the first lateral surface of the corresponding one of the second semiconductor laser elements,
in the top view, a midpoint of a width of the light-emitting surface of each of the first semiconductor laser elements does not coincide with a midpoint of a width of a corresponding one of the first submounts in a direction parallel to the light-emitting surface of each of the first semiconductor laser elements, and
in the top view, a midpoint of a width of the light-emitting surface of each of the second semiconductor laser elements does not coincide with a midpoint of a width of a corresponding one of the second submounts in a direction parallel to the light-emitting surface of each of the second semiconductor laser elements.

10. The light-emitting module according to claim 9, wherein
in the top view, the midpoint of the width of the light-emitting surface of each of the first semiconductor laser elements is separated from the midpoint of the width of a corresponding one of the first submounts by a range from 10 μm to 200 μm in a direction parallel to the light-emitting surface of each of the first semiconductor laser elements, and
in the top view, the midpoint of the width of the light-emitting surface of each of the second semiconductor laser elements is separated from the midpoint of the width of a corresponding one of the second submounts by a range from 10 μm to 200 μm in a direction parallel to the light-emitting surface of each of the second semiconductor laser elements.

11. The light-emitting module according to claim 9, wherein
the first submounts are arranged side by side such that an interval between adjacent ones of the first submounts is 300 μm or less, and
the second submounts are arranged side by side such that an interval between adjacent ones of the second submounts is 300 μm or less.

12. A plurality of light-emitting devices comprising:
a first light-emitting device including
a plurality of first semiconductor laser elements each having a light-emitting surface and a first lateral surface opposite to the light-emitting surface,
a plurality of first protective elements, and
a plurality of first submounts each including a first mounting surface on which a first wiring layer is provided, the first wiring layer including a first region and a second region, the first region being a region on which a corresponding one of the first semiconductor laser elements is disposed, and the second region being a region on which a corresponding one of the first protective elements is disposed; and
a second light-emitting device including
a plurality of second semiconductor laser elements each having a light-emitting surface and a second lateral surface opposite to the light-emitting surface,
a plurality of second protective elements, and
a plurality of second submounts each including a second mounting surface on which a second wiring layer is provided, the second wiring layer including a first region and a second region, the first region being a region on which a corresponding one of the second semiconductor laser elements is disposed, and the second region being a region on which a corresponding one of the second protective elements is disposed, wherein
a shape of the first wiring layer of each of the first submounts when viewed from a direction perpendicular to the first mounting surface is identical to a shape of the second wiring layer of each of the second submounts when viewed from a direction perpendicular to the second mounting surface,
in a top view, each of the first protective elements is not placed between a first virtual straight line and a second virtual straight line, the first virtual straight line passing through and being parallel to the light-emitting surface of a corresponding one of the first semiconductor laser elements, and the second virtual straight line passing through and being parallel to the first lateral surface of the corresponding one of the first semiconductor laser elements,
in the top view, a part or all of each of the second protective elements is placed between a third virtual straight line and a fourth straight line, the third straight line passing through and being parallel to the light-emitting surface of a corresponding one of the second semiconductor laser elements, and the fourth virtual straight line passing through and being parallel to the first lateral surface of the corresponding one of the second semiconductor laser elements,
in the top view, a midpoint of a width of the light-emitting surface of each of the first semiconductor laser elements does not coincide with a midpoint of a width of a corresponding one of the first submounts in a direction parallel to the light-emitting surface of each of the first semiconductor laser elements, and
in the top view, a midpoint of a width of the light-emitting surface of each of the second semiconductor laser elements does not coincide with a midpoint of a width of a corresponding one of the second submounts in a direction parallel to the light-emitting surface of each of the second semiconductor laser elements.

13. The plurality of light-emitting devices according to claim 12, wherein
in the top view, the midpoint of the width of the light-emitting surface of each of the first semiconductor laser elements is separated from the midpoint of the width of the corresponding one of the first submounts by a range from 10 μm to 200 μm in a direction parallel to the light-emitting surface of each of the first semiconductor laser elements, and
in the top view, the midpoint of the width of the light-emitting surface of each of the second semiconductor laser elements is separated from the midpoint of the width of the corresponding one of the second submounts by a range from 10 μm to 200 μm in a direction parallel to the light-emitting surface of each of the second semiconductor laser elements.

14. The plurality of light-emitting devices according to claim 12, wherein
the first submounts are arranged side by side such that an interval between adjacent ones of the first submounts is 300 μm or less, and
the second submounts are arranged side by side such that an interval between adjacent ones of the second submounts is 300 μm or less.

15. The plurality of light-emitting devices according to claim 12, wherein
the first light-emitting device and the second light-emitting device are assigned to an identical consumer or different consumers.
